(19) United States
(12) Patent Application Publication
(10) Pub. No.: US 2024/0234632 A1
(43) Pub. Date: Jul. 11, 2024

(54) LIGHT-EMITTING ELEMENT, DISPLAY DEVICE, AND LIGHT-EMITTING ELEMENT MANUFACTURING METHOD

(71) Applicant: Sharp Display Technology Corporation, Kameyama City, Mie (JP)

(72) Inventors: Takahiro ADACHI, Kameyama City, Mie (JP); Yasushi ASAOKA, Kameyama City, Mie (JP); Sentaro KIDA, Kameyama City, Mie (JP)

(21) Appl. No.: 18/559,477

(22) PCT Filed: Jun. 30, 2021
(86) PCT No.: PCT/JP2021/024870

§ 371 Date: Nov. 7, 2023

(51) Int. Cl. H01L 33/24; H01L 25/075; H01L 33/38

(52) U.S. Cl. CPC H01L 33/24; H01L 25/0753; H01L 33/38

(57) ABSTRACT

A light-emitting element according to the disclosure includes a bank including a base portion and a first protruding portion protruding from an upper face of the base portion, and a red light-emitting layer, in which at least a part of an end portion of the red light-emitting layer is located above the upper face of the base portion or adjacently to a side face of the first protruding portion.

### TECHNICAL FIELD

The disclosure relates to a light-emitting element, a display device, and a light-emitting element manufacturing method.

### BACKGROUND ART

Known methods for forming a pattern include a method using a printing technique such as an ink-jet method and a method using a photolithography technique such as a lift-off method.

PTL 1 discloses a method for forming a pattern of a conductive film using the lift-off method.

PTLs 2 to 4 disclose a method for forming a pattern of a function layer in a light-emitting element using the ink-jet method, and a bank including an upper face provided with a groove.

### CITATION LIST

### Patent Literature

PTL 1: JP 2011-35282 A (published on Feb. 17, 2011)
PTL 2: JP 2014-123527 A (published on Jul. 3, 2014)
PTL 3: JP 2005-276479 A (published on Oct. 6, 2005)
PTL 4: Republished WO2012/017498 (Internationally Published Feb. 9, 2012)

### SUMMARY

### Technical Problem

There is a problem in the method for forming a pattern using the lift-off method in that burrs are generated at an end portion of a patterned function layer such that the burrs are peeled off, or the function layer is peeled off from an end face as a starting point.

### Solution to Problem

To resolve such a problem, a light-emitting element according to an aspect of the disclosure includes a bank including a base portion and a first protruding portion protruding from an upper face of the base portion, and a first function layer, and is configured such that at least a part of an end portion of the first function layer is located above the upper face of the base portion or adjacently to a side face of the first protruding portion.

The light-emitting element according to an aspect of the disclosure may be configured such that at least a part of the first function layer is formed extending over the first protruding portion.

The light-emitting element according to an aspect of the disclosure may be configured such that an inclination angle of the side face of the first protruding portion is less than 90 degrees.

The light-emitting element according to an aspect of the disclosure may be configured such that a step between the upper face of the base portion and an upper face of the first protruding portion is less than 10 μm.

The light-emitting element according to an aspect of the disclosure may be configured such that the at least a part of the end portion of the first function layer is located above the upper face of the base portion.

The light-emitting element according to an aspect of the disclosure may be configured such that the first function layer has a thick end portion as compared to a portion formed in an opening of the bank.

The light-emitting element according to an aspect of the disclosure may be configured such that the first function layer includes at least any one layer of a light-emitting layer, a charge transport layer, and a charge injection layer.

The light-emitting element according to an aspect of the disclosure may be configured such that the bank further includes a second protruding portion protruding from the upper face of the base portion, and the at least a part of the end portion of the first function layer is located between the first protruding portion and the second protruding portion.

The light-emitting element according to an aspect of the disclosure may be configured such that a step between the upper face of the base portion and the upper face of the first protruding portion is larger than a thickness of the at least a part of the end portion of the first function layer, and a step between the upper face of the base portion and the upper face of the second protruding portion is larger than the thickness of the at least a part of the end portion of the first function layer.

The light-emitting element according to an aspect of the disclosure may be configured such that the first protruding portion surrounds an opening of the bank, and an entire part of the end portion of the first function layer is located above the upper face of the base portion or adjacently to the side face of the first protruding portion.

The light-emitting element according to an aspect of the disclosure may be configured such that the first protruding portion does not surround an opening of the bank.

The light-emitting element according to an aspect of the disclosure may be configured such that at least one side face of the first protruding portion includes a meandering shape or a zigzag shape.

The light-emitting element according to an aspect of the disclosure may be configured such that the first function layer includes a plurality of layers.

The light-emitting element according to an aspect of the disclosure further includes an insulating layer and an island-shaped electrode located on the insulating layer, and may be configured such that the bank covers an end portion of the island-shaped electrode, a distance from an upper face of the insulating layer to the upper face of the base portion is equivalent to a distance from a surface of the end portion of the island-shaped electrode to the upper face of the first protruding portion, the island-shaped electrode has a uniform thickness, and the first protruding portion is located above the end portion of the island-shaped electrode.

The light-emitting element according to an aspect of the disclosure further includes an insulating layer and an island-shaped electrode located on the insulating layer, and may be configured such that the bank covers an end portion of the island-shaped electrode, a distance from an upper face of the insulating layer to the upper face of the base portion is equivalent to a distance from an upper face of the island-shaped electrode to the upper face of the first protruding portion, at least a part of the end portion of the island-shaped electrode is thicker than a central portion of the island-shaped electrode corresponding to an opening of the bank, and the first protruding portion is located above the at least a part of the end portion of the island-shaped electrode.

The light-emitting element according to an aspect of the disclosure further includes an insulating layer including a flat portion and a depressed portion depressed from the flat portion, and may be configured such that the bank covers the depressed portion, and the first protruding portion is located above the flat portion.

A display device according to an aspect of the disclosure is configured to include the above-described light-emitting element.

The display device according to an aspect of the disclosure includes a second function layer including an end portion formed above the bank and located on a side opposite to the first function layer with respect to the bank, and may be configured such that at least a part of the second function layer is located above the upper face of the base portion or adjacently to the side face of the first protruding portion.

The display device according to an aspect of the disclosure includes a second function layer including an end portion formed above the bank and located on a side opposite to the first function layer with respect to the bank, and may be configured such that the bank further includes a second protruding portion protruding from the upper face of the base portion, and at least a part of an end portion of the second function layer is located between the first protruding portion and the second protruding portion.

The display device according to an aspect of the disclosure may be configured such that the bank further includes a third protruding portion protruding from the upper face of the base portion and being located between the first protruding portion and the second protruding portion, at least a part of the first function layer is formed extending over the first protruding portion, at least a part of the second function layer is formed extending over the second protruding portion, the at least a part of the end portion of the first function layer is located between the first protruding portion and the third protruding portion, and the at least a part of the end portion of the second function layer is located between the second protruding portion and the third protruding portion.

The display device according to an aspect of the disclosure may be configured such that the bank further includes a third protruding portion protruding from the upper face of the base portion and located between the first protruding portion and the second protruding portion, at least a part of the first function layer is formed extending over the first protruding portion and the third protruding portion, at least a part of the second function layer is formed extending over the second protruding portion and the third protruding portion, the at least a part of the end portion of the first function layer is located between the second protruding portion and the third protruding portion, and the at least a part of the end portion of the second function layer is located between the first protruding portion and the third protruding portion.

To resolve the above problems, there is provided a method of manufacturing a light-emitting element according to an aspect of the disclosure, including forming a bank so that the bank includes a base portion and a first protruding portion protruding from an upper face of the base portion, forming a sacrificing layer so that the sacrificing layer covers the bank, patterning the sacrificing layer so that an end portion of the sacrificing layer is located above the bank and at least a part of the end portion of the sacrificing layer is located above the upper face of the base portion or adjacently to a side face of the first protruding portion, forming a function material layer so that the function material layer covers the sacrificing layer and the bank, and patterning the function material layer by dissolving at least a part of the sacrificing layer.

The method of manufacturing a light-emitting element according to an aspect of the disclosure is a method of manufacturing a light-emitting element described above. The forming a bank includes forming a photoresist layer, and exposing the photoresist layer using a photomask including a light-transmitting portion with a high light transmittance, a light blocking portion with a low light transmittance, and a semi-transparent portion with an intermediate light transmittance between a light transmittance of the light-transmitting portion and a light transmittance of the light blocking portion. An opening of the bank is formed at a position corresponding to one of the light-transmitting portion and the light blocking portion, and the first protruding portion is formed at a position corresponding to the other of the light-transmitting portion and the light blocking portion.

### Advantageous Effects of Disclosure

According to an aspect of the disclosure, it is possible to reduce the above-described problem that the end portion of the function layer or the function layer itself is easily peeled off.

### BRIEF DESCRIPTION OF DRAWINGS

FIG. 1 is a conceptional view illustrating a schematic configuration of a display device according to an embodiment of the disclosure.

FIG. 2 is a schematic cross-sectional view illustrating an example of a configuration of a display region DA of the display device illustrated in FIG. 1.

FIG. 3 is a schematic cross-sectional view illustrating an example of a configuration of a light-emitting element layer according to the disclosure.

FIG. 4 is a schematic plan view illustrating an example of a positional relationship between a light-emitting layer and a bank in the light-emitting element layer illustrated in FIG. 3.

FIG. 5 is a schematic flowchart illustrating an example of a method of manufacturing the light-emitting element layer illustrated in FIG. 3.

FIG. 6 is a schematic flowchart illustrating an example of a method of manufacturing the bank illustrated in FIG. 3.

FIG. 7 is a schematic flowchart illustrating an example of a method of manufacturing the light-emitting layer illustrated in FIG. 3.

FIG. 8 is a schematic cross-sectional view illustrating an example of a method of manufacturing the light-emitting element layer illustrated in FIG. 3.

FIG. 9 is a schematic cross-sectional view illustrating an example of a method of manufacturing the light-emitting element layer illustrated in FIG. 3.

FIG. 10 is a schematic cross-sectional view illustrating an example of a method of manufacturing the light-emitting element layer illustrated in FIG. 3.

FIG. 11 is a schematic cross-sectional view illustrating an example of a method of manufacturing the light-emitting element layer illustrated in FIG. 3.

FIG. 12 is a schematic cross-sectional view illustrating an example of a method of manufacturing the light-emitting element layer illustrated in FIG. 3.

FIG. 13 is a schematic cross-sectional view illustrating an example of a method of manufacturing the light-emitting element layer illustrated in FIG. 3.

FIG. 14 is a schematic cross-sectional view illustrating an example of a method of manufacturing the light-emitting element layer illustrated in FIG. 3.

FIG. 15 is a schematic cross-sectional view illustrating a configuration of an end portion 42 of a light-emitting layer 40 illustrated in FIG. 3.

FIG. 16 is a schematic cross-sectional view illustrating a configuration of a light-emitting element layer according to a comparative example.

FIG. 17 is an enlarged schematic partial cross-sectional view illustrating a portion of a configuration of the light-emitting element layer according to the comparative example in an enlarged manner.

FIG. 18 is an enlarged schematic partial cross-sectional view illustrating a portion of a configuration of the light-emitting element layer according to the disclosure illustrated in FIG. 3 in an enlarged manner.

FIG. 19 is a schematic plan view illustrating a modified example of the positional relationship between the light-emitting layer and the bank in the light-emitting element layer 5 illustrated in FIG. 3.

FIG. 20 is a schematic plan view illustrating a modified example of the positional relationship between the light-emitting layer and the bank in the light-emitting element layer 5 illustrated in FIG. 3.

FIG. 21 is a schematic cross-sectional view illustrating an example of a configuration of the light-emitting element layer according to the disclosure.

FIG. 22 is a schematic cross-sectional view illustrating an example of the method of manufacturing the light-emitting element layer illustrated in FIG. 21.

FIG. 23 is a schematic cross-sectional view illustrating a modified example of the light-emitting element layer 5 illustrated in FIG. 21.

FIG. 24 is a schematic cross-sectional view illustrating an example of a configuration of the light-emitting element layer according to the disclosure.

FIG. 25 is a schematic cross-sectional view illustrating an example of a method of manufacturing a light-emitting element layer illustrated in FIG. 24.

FIG. 26 is a schematic cross-sectional view illustrating an example of a configuration of the light-emitting element layer according to the disclosure.

FIG. 27 is a schematic cross-sectional view illustrating an example of a method of manufacturing a light-emitting element layer illustrated in FIG. 26.

FIG. 28 is a schematic cross-sectional view illustrating an example of a configuration of the light-emitting element layer according to the disclosure.

FIG. 29 is a schematic cross-sectional view illustrating an example of a configuration of the light-emitting element layer according to the disclosure.

FIG. 30 is a schematic cross-sectional view illustrating an example of a configuration of the light-emitting element layer according to the disclosure.

FIG. 31 is a schematic cross-sectional view illustrating an example of a configuration of the light-emitting element layer according to the disclosure.

### DESCRIPTION OF EMBODIMENTS

### First Embodiment

### Display Device

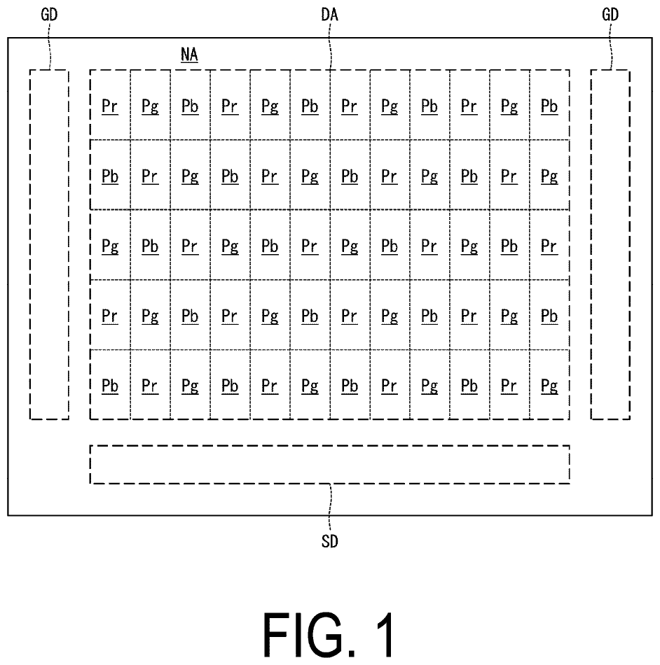

FIG. 1 is a conceptional view illustrating a schematic configuration of a display device 1 according to an embodiment of the disclosure.

As illustrated in FIG. 1, the display device 1 includes a display region DA and a frame region NA surrounding the display region DA.

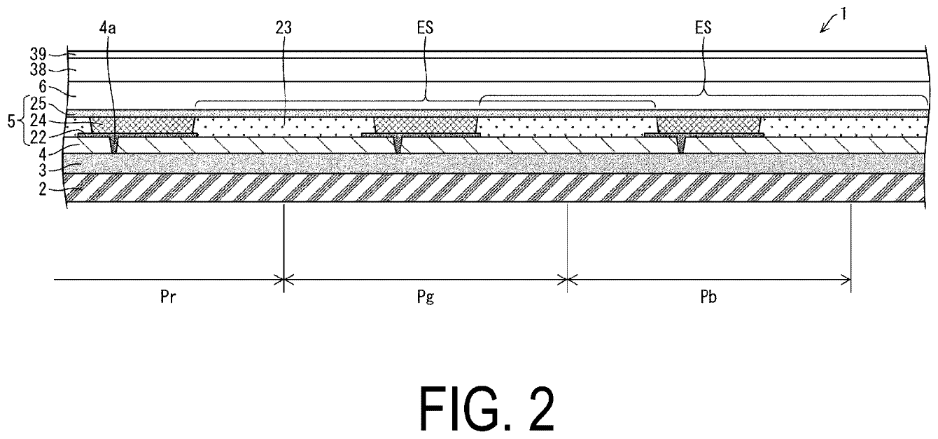

The display region DA is provided with a red subpixel Pr corresponding to a light-emitting element ES (see FIG. 2) configured to emit red light, a green subpixel Pg corresponding to a light-emitting element ES configured to emit green light, and a blue subpixel Pb corresponding to a light-emitting element ES configured to emit blue light. Hereinafter, the red subpixel Pr, the green subpixel Pg, and the blue subpixel Pb are collectively referred to as “subpixels P”. Although FIG. 1 illustrates an example in which the subpixels P are arranged in an oblique arrangement, the arrangement is not limited thereto, and the subpixels P may be arranged in any arrangement such as a stripe arrangement or a pentile arrangement. Each of the subpixels P includes a pixel circuit configured to control the corresponding light-emitting element ES, and has a one-to-one correspondence with the light-emitting element ES according to the disclosure.

The frame region NA is formed with a gate driver GD, a source driver SD, wiring lines (not illustrated) connecting the display region DA to the gate driver GD and the source driver SD, wiring lines and terminals (not illustrated) for supplying electric power and signals to the gate driver GD and the source driver SD, and the like.

FIG. 2 is a schematic cross-sectional view illustrating an example of a configuration of the display region DA of the display device 1 illustrated in FIG. 1.

As illustrated in FIG. 2, when the display device 1 according to the disclosure is a non-flexible display device, the display device 1 includes, for example, a glass substrate 2, a thin film transistor layer 3, a flattening film 4, a light-emitting element layer 5, a sealing layer 6, an adhesive layer 38, and a function film 39.

As illustrated in FIG. 2, the light-emitting element layer 5 includes a pixel electrode 22, a bank 23 covering an end portion of the pixel electrode 22, an active layer 24 covering the pixel electrode 22, and a common electrode 25 covering the active layer 24, and configures a light-emitting element ES.

The pixel electrode 22 is an island-shaped electrode provided for each of the subpixels P.

For example, the bank 23 is formed to cover an end portion (that is, an “edge”) of the pixel electrode 22. Therefore, the bank 23 is also referred to as an “edge cover”. The light-emitting element ES in the disclosure includes the bank 23 surrounding the corresponding pixel electrode 22.

The active layer 24 is an EL layer that performs electroluminescence (EL) or includes the EL layer. The active layer 24 is formed to cover the pixel electrode 22 exposed from an opening of the bank 23.

The common electrode 25 is an electrode provided in common to all the subpixels P.

Hereinafter, in order to facilitate understanding of the disclosure, the light-emitting element layer 5 will be described in detail, and the other layers will not be described in detail.

Although the disclosure describes an example in which the display device 1 is a non-flexible display device, the disclosure is not limited thereto, and a flexible display device is also included within the scope of the disclosure.

Although the disclosure is described with respect to an example in which the pixel electrode 22 is an anode and the common electrode 25 is a cathode, the disclosure is not limited thereto, and an example in which the pixel electrode 22 is a cathode and the common electrode 25 is an anode is also included within the scope of the disclosure. The display device 1 may appropriately include an additional layer, and for example, may include a barrier layer in order to reduce entry of oxygen or moisture into the light-emitting element layer 5. The barrier layer may be provided between the glass substrate 2 and the thin film transistor layer 3.

Although the disclosure is described with respect to an example in which the bank 23 corresponding to the plurality of light-emitting elements ES is integrally formed and the adjacent light-emitting elements ES share the bank 23, the disclosure is not limited thereto, and an example in which banks 23 corresponding to the respective light-emitting elements ES are separately formed and the light-emitting elements ES do not share the banks 23 is also included within the scope of the disclosure.

### Configuration of Light-Emitting Element Layer

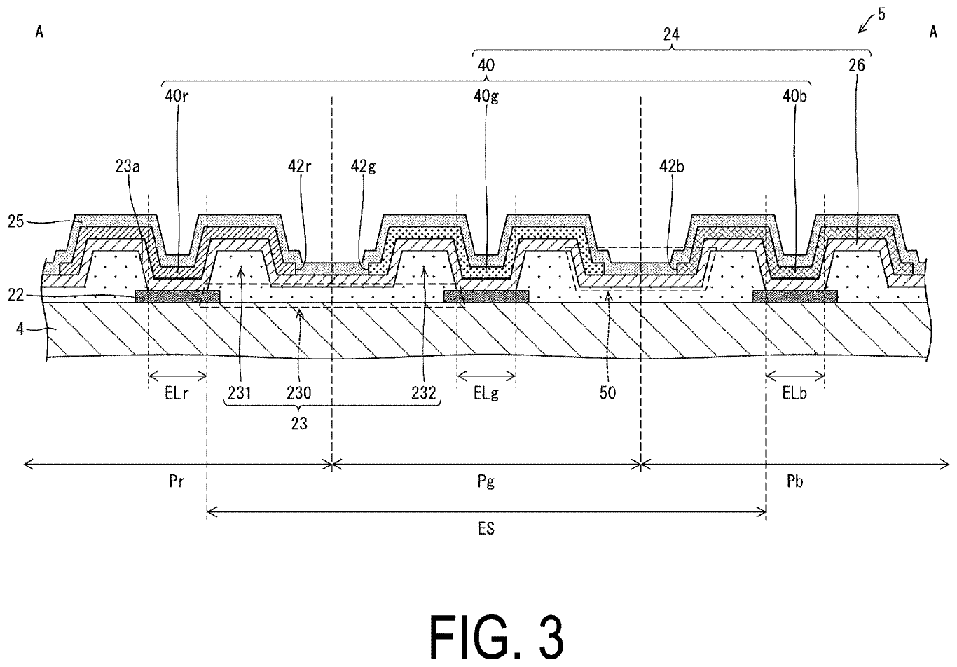

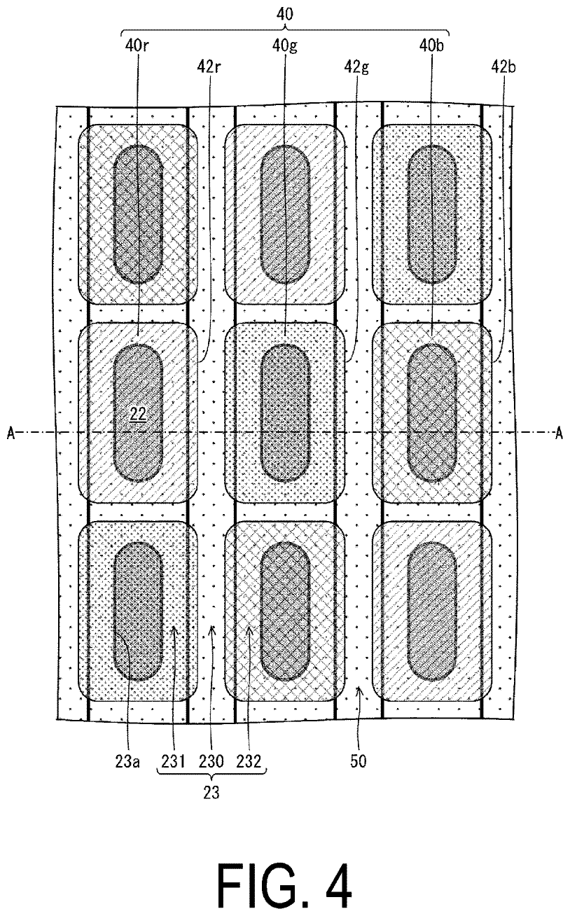

FIG. 3 is a schematic cross-sectional view illustrating an example of a configuration of the light-emitting element layer 5 according to the disclosure. FIG. 4 is a schematic plan view illustrating an example of a positional relationship between the light-emitting layer 40 and the bank 23 in the light-emitting element layer 5 illustrated in FIG. 3. FIG. 3 corresponds to a cross-sectional view taken along AA in FIG. 4.

In an example illustrated in FIG. 3, the pixel electrode 22 is an anode and the common electrode 25 is a cathode.

As illustrated in FIG. 3, the active layer 24 includes a hole injection layer 26 and a light-emitting layer 40. The active layer 24 may optionally include additional layers such as a hole transport layer, an electron transport layer, and an electron injection layer. If it is possible to directly inject a hole from the cathode to the light-emitting layer 40, the active layer 24 may not include the hole injection layer 26.

The hole injection layer 26 and the hole transport layer include a hole transport material and/or a photosensitive hole transport material. Examples of the hole transport material include NiO, CuI, Cu₂O, CoO, Cr₂O₃, and CuAlS₂. Examples of the photosensitive hole transport material includes OTPD, QUPD, and X-F6-TAPC.

Examples of the electron transport layer and the electron injection layer include ZnO, ZnS, ZrO, MgZnO, AlZnO, and TiO₂.

The light-emitting layer 40 includes an inorganic light-emitting material or an organic light-emitting material such as quantum dots emitting light by recombination of electrons and holes. The quantum dot may be a core type, a core-shell type, or a core-multishell type. Examples of the core material and the shell material in the core-shell type quantum dots include CDSE/CdS, CdSe/ZnS, CdTe/CdS, InP/ZnS, GaP/ZnS, Si/ZnS, InN/GaN, InP/CdSSe, InP/ZNSeTe, GaInP/ZNSe, GaInP/ZnS, Si/AIP, InP/ZnSTe, GaInP/ZnSTe, and GaInP/ZnSSe.

The light-emitting layer 40 includes a red light-emitting layer 40r formed in the light-emitting element ES corresponding to the red subpixel Pr, a green light-emitting layer 40g formed in the light-emitting element ES corresponding to the green subpixel Pg, and a blue light-emitting layer 40b formed in the light-emitting element ES corresponding to the blue subpixel Pb. The red light-emitting layer 40r includes a light-emitting material that emits red light by electroluminescence. The green light-emitting layer 40g includes a light-emitting material that emits green light by electroluminescence. The blue light-emitting layer 40b includes a light-emitting material that emits blue light by electroluminescence.

The bank 23 includes a base portion 230, a first protruding portion 231 protruding from an upper face of the base portion 230, and a second protruding portion 232 protruding from an upper face of the base portion 230. Between the first protruding portion 231 and the second protruding portion 232, a recessed portion 50 is formed.

As illustrated in FIG. 4, an end portion 42r of the red light-emitting layer 40r is located above the bank 23. An end portion 42g of the green light-emitting layer 40g is located above the bank 23. An end portion 42b of the blue light-emitting layer 40b is located above the bank 23. A positional relationship between the light-emitting layer 40 and the bank 23 will be described in detail later.

### Manufacturing Method

A method of manufacturing the light-emitting element layer 5 illustrated in FIG. 3 will be described in detail below. The method of manufacturing the light-emitting element layer 5 is also referred to as a method of manufacturing the light-emitting element ES. The method of manufacturing the light-emitting element layer 5 is a part of the method of manufacturing the display device 1.

In the following description, the “same layer” means a layer formed through the same process (film formation step), the “lower layer” means a layer formed through a process before that of the layer to be compared, and the “upper layer” means a layer formed through a process after that of the layer to be compared.

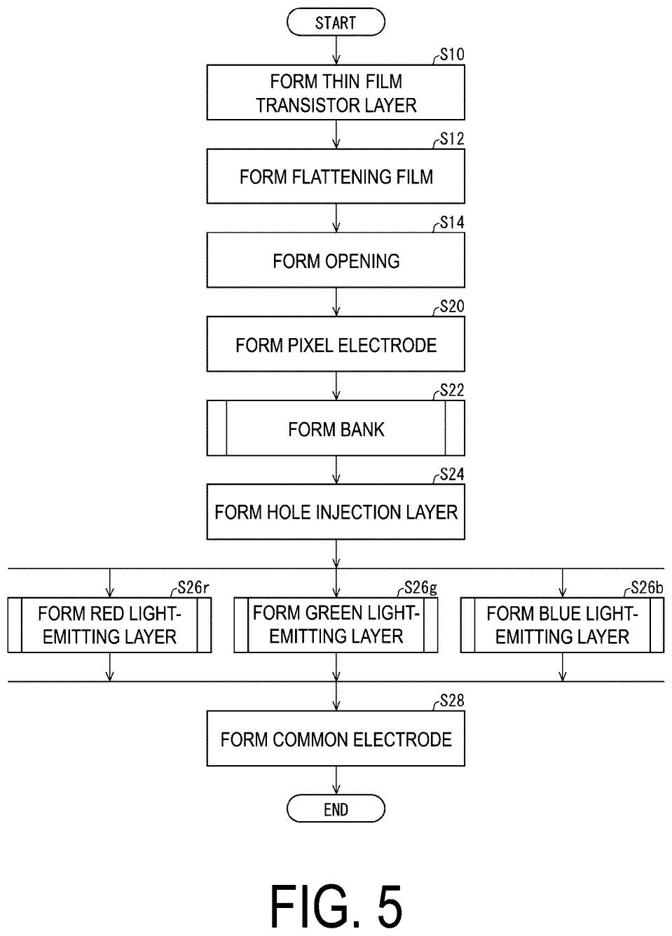

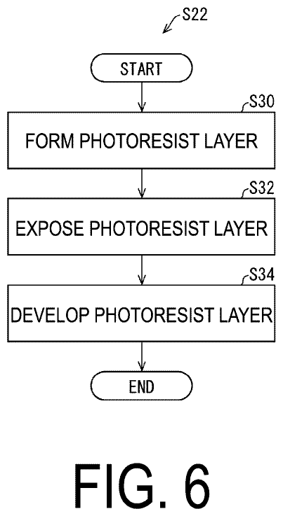

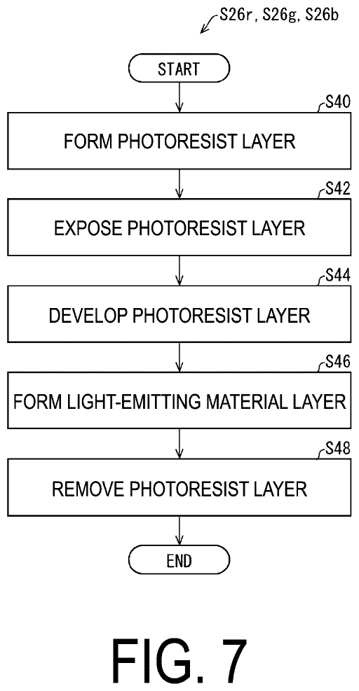

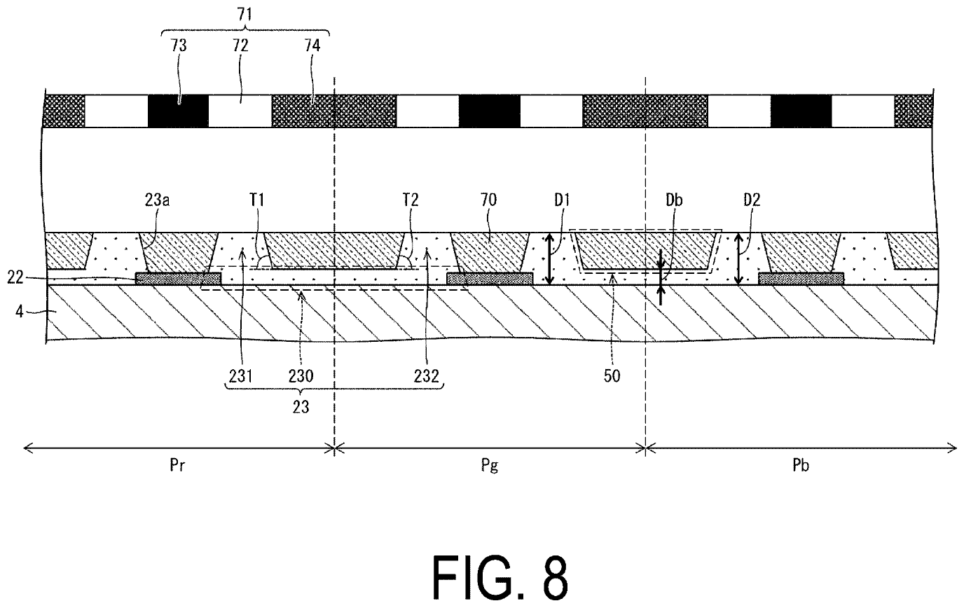

FIG. 5 is a schematic flowchart illustrating an example of the method of manufacturing the light-emitting element layer 5 illustrated in FIG. 3. FIG. 6 is a schematic flowchart illustrating an example of a method of manufacturing the bank 23 illustrated in FIG. 3. FIG. 7 is a schematic flowchart illustrating an example of a method of manufacturing the light-emitting layer 40 illustrated in FIG. 3. FIG. 8 to FIG. 14 are schematic cross-sectional views each illustrating an example of a method of manufacturing the light-emitting element layer 5 illustrated in FIG. 3.

Below, for simplification of description, a detailed description will be given while focusing on the red light-emitting layer 40r (first function layer), the green light-emitting layer 40g (second function layer), and the bank 23 above which the end portion 42r of the red light-emitting layer 40r and the end portion 42g of the green light-emitting layer 40g are located. In addition, out of the two protruding portions included in the bank 23 to be focused on, the protruding portion close to the red light-emitting layer 40r is referred to as the first protruding portion 231, and the protruding portion close to the green light-emitting layer 40g is referred to as the second protruding portion 232. The green light-emitting layer 40g is located on the opposite side of the red light-emitting layer 40r with respect to the bank 23 to be focused on.

As illustrated in FIG. 5, the thin film transistor layer 3 is formed on the glass substrate 2 (step S10), the flattening film 4 is formed on the thin film transistor layer 3 (step S12), an opening including a through hole 4a is provided in the flattening film 4 (step S14), and the pixel electrode 22 is formed on the flattening film 4 (step S20). Next, the bank 23 is formed by using a photolithography technique (step S22).

As illustrated in FIG. 6 and FIG. 8, in step S22, firstly, a photoresist layer 70 is formed as a bank material layer to cover the flattening film 4 and the pixel electrode 22 (step S30). The photoresist layer 70 includes a photoresist. Examples of the photoresist include acrylic-based, novolac-based, rubber-based, styrene-based, and epoxy-based photoresists. Such a photoresist may include a positive photoresist (hereinafter referred to as a “positive resist”) or a negative photoresist (hereinafter referred to as a “negative resist”). Therefore, the positive resist is insoluble in a developing solution before exposure, and is soluble in the developing solution after exposure. The negative resist is soluble in the developing solution before exposure and insoluble in the developing solution after exposure.

Next, the photoresist layer 70 is exposed to ultraviolet rays, electron beams, laser beams, and the like by using a photomask 71 (step S32). The photomask 71 is a half-tone mask or a gray-tone mask, and includes a light-transmitting portion 72 with a high light transmittance, a light blocking portion 73 with a low light transmittance, and a semi-transparent portion 74 with an intermediate light transmittance between that of the light-transmitting portion 72 and that of the light blocking portion 73. When the photoresist layer 70 includes the negative resist as a result of such an exposure (see FIG. 8), a portion of the photoresist layer 70 corresponding to the light-transmitting portion 72 is insoluble in the developing solution. A portion of the photoresist layer 70 corresponding to the light blocking portion 73 remains soluble in the developing solution. A part of the portion of the photoresist layer 70 corresponding to the semi-transparent portion 74 is insoluble in the developing solution.

When the photoresist layer 70 includes the positive resist (not illustrated), a portion of the photoresist layer 70 corresponding to the light blocking portion 73 remains insoluble in the developing solution in step S32. A portion of the photoresist layer 70 corresponding to the light-transmitting portion 72 is soluble in the developing solution. A part of the portion of the photoresist layer 70 corresponding to the semi-transparent portion 74 is soluble in the developing solution.

Next, the photoresist layer 70 is developed using a developing solution (step S34). The developing solution may be an aqueous solution containing an inorganic alkali such as KOH or NaOH, an aqueous solution containing an organic alkali such as TMAH, or an organic solvent such as PGMEA, acetone, NMP, DMSO, and IPA.

By the process described above, when the photoresist layer 70 includes the negative resist (see FIG. 8), the base portion 230 of the bank 23 is formed from a portion corresponding to the light-transmitting portion 72 and the semi-transparent portion 74 of the photoresist layer 70. From a portion corresponding to the light-transmitting portion 72 of the photoresist layer 70, the first protruding portion 231 and the second protruding portion 232 of the bank 23 are formed. A portion corresponding to the light blocking portion 73 of the photoresist layer 70 is removed to form the opening 23a of the bank 23.

When the photoresist layer 70 includes the positive resist (not illustrated), the base portion 230 of the bank 23 is formed from a portion corresponding to the light blocking portion 73 and the semi-transparent portion 74 of the photoresist layer 70. From a portion corresponding to the light blocking portion 73 of the photoresist layer 70, the first protruding portion 231 and the second protruding portion 232 of the bank 23 are formed. A portion corresponding to the light-transmitting portion 72 of the photoresist layer 70 is removed to form the opening 23a of the bank 23.

That is, one of the light-transmitting portion 72 and the light blocking portion 73 of the photomask 71 corresponds to the first protruding portion 231 and the second protruding portion 232 of the bank 23, and the other corresponds to the opening 23a of the bank 23.

The bank 23 may be formed by a process other than the process described above. For example, the bank 23 may be formed by a so-called etching method. In such a case, a bank material layer is formed, a photoresist layer is formed as a template layer on the bank material layer, the photoresist layer is exposed and developed to obtain a template, and the bank material layer is etched using such a template as a mask. Such etching is usually dry etching. For example, a sequence including forming, exposing, and developing the photoresist layer may be repeated two or more times without using a half-tone mask or a gray-tone mask.

A thickness Db of the base portion 230 is smaller than a thickness D1 of the first protruding portion 231 and a thickness D2 of the second protruding portion 232 (Db<D1 and Db<D2). The thickness D1 of the first protruding portion 231 and the thickness D2 of the second protruding portion 232 may be different from or the same as each other. In order to simplify the manufacturing method, the thickness D1 of the first protruding portion 231 and the thickness D2 of the second protruding portion 232 are preferably the same.

In order to reduce film discontinuity of an upper layer overlying the bank 23, it is preferable that a step (D1-Db) between the upper face of the base portion 230 and the upper face of the first protruding portion 231 not be too large. Similarly, it is preferable that a step (D2-Db) between the upper face of the base portion 230 and the upper face of the second protruding portion 232 not be too large. For example, these steps are preferably less than 10 μm.

In order to reduce film discontinuity of an upper layer overlying the bank 23, an inclination angle T1 of a side face of the first protruding portion 231 and an inclination angle T2 of a side face of the second protruding portion are preferably smaller than 90 degrees. The inclination angle T1 of the first protruding portion 231 and the inclination angle T2 of the second protruding portion may be different from or the same as each other. In order to simplify the manufacturing method, the thickness D1 of the first protruding portion 231 and the thickness D2 of the second protruding portion 232 are preferably the same.

As illustrated in FIG. 5, next, the hole injection layer 26 is formed (step S24). Subsequently, formation of the red light-emitting layer 40r (step S26r), formation of the green light-emitting layer 40g (step S26g), and formation of the blue light-emitting layer 40b (step S26b) are performed in any order. Subsequently, the common electrode 25 is formed (step S28).

In an example, a case where step S26r, step S26g, and step S26b are performed in this order will be described below.

### Formation of Red Light-Emitting Layer 40r

The formation of the red light-emitting layer 40r (step S26r) will be described below.

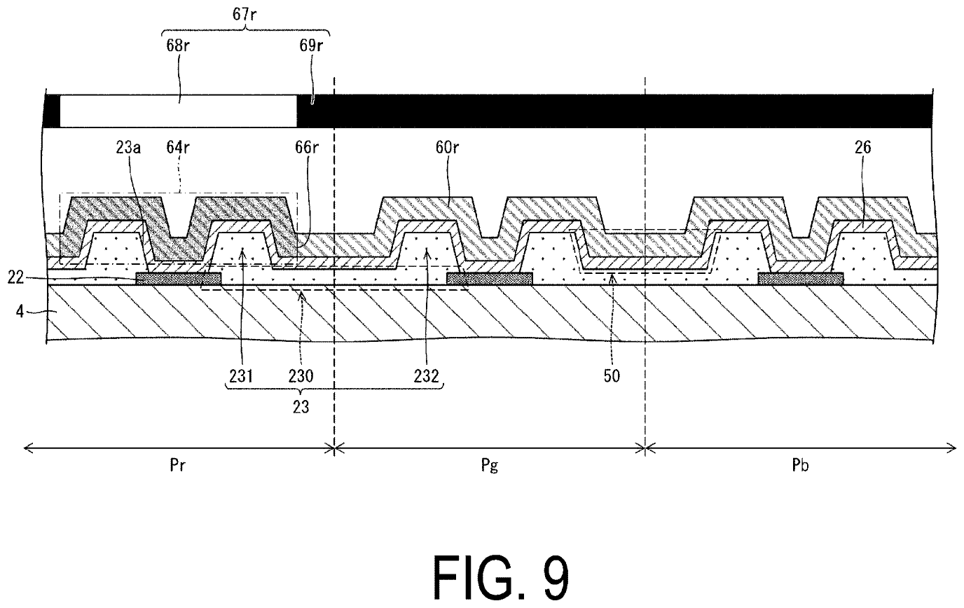

As illustrated in FIG. 9, in step S26r, first, a photoresist layer 60r (sacrificing layer) is formed on the hole injection layer 26 so that the photoresist layer 60r covers the pixel electrode 22 and the bank 23 (step S40). The photoresist layer 60r includes a photoresist. Examples of the photoresist include acrylic-based, novolac-based, rubber-based, styrene-based, and epoxy-based photoresists. The photoresist may include the positive resist or the negative resist.

Next, the photoresist layer 60r is exposed to ultraviolet rays, electron beams, laser beams, and the like by using a photomask 67r (step S42). The photomask 67r includes a light-transmitting portion 68r with a high light transmittance and a light blocking portion 69r with a low light transmittance. As a result of such exposure, when the photoresist layer 60r includes the positive resist (see FIG. 9), a portion corresponding to the light-transmitting portion 68r of the photoresist layer 60r is soluble in a developing solution. A portion corresponding to the light blocking portion 69r of the photoresist layer 60r remains insoluble in the developing solution. Here, a portion corresponding to the light blocking portion 69r of the photoresist layer 60r is referred to as a removed portion 64r.

When the photoresist layer 60r includes the negative resist (not illustrated), a portion corresponding to the light blocking portion 69r of the photoresist layer 60r remains soluble in the developing solution. A portion corresponding to the light-transmitting portion 68r of the photoresist layer 60r is insoluble in the developing solution. Therefore, a portion corresponding to the light-transmitting portion 68r of the photoresist layer 60r is referred to as the removed portion 64r.

Next, a developing solution is used to develop the photoresist layer 60r (step S44). The developing solution may be an aqueous solution containing an inorganic alkali such as KOH or NaOH, an aqueous solution containing an organic alkali such as TMAH, or an organic solvent such as PGMEA, acetone, NMP, DMSO, and IPA. The removed portion 64r is removed by the development.

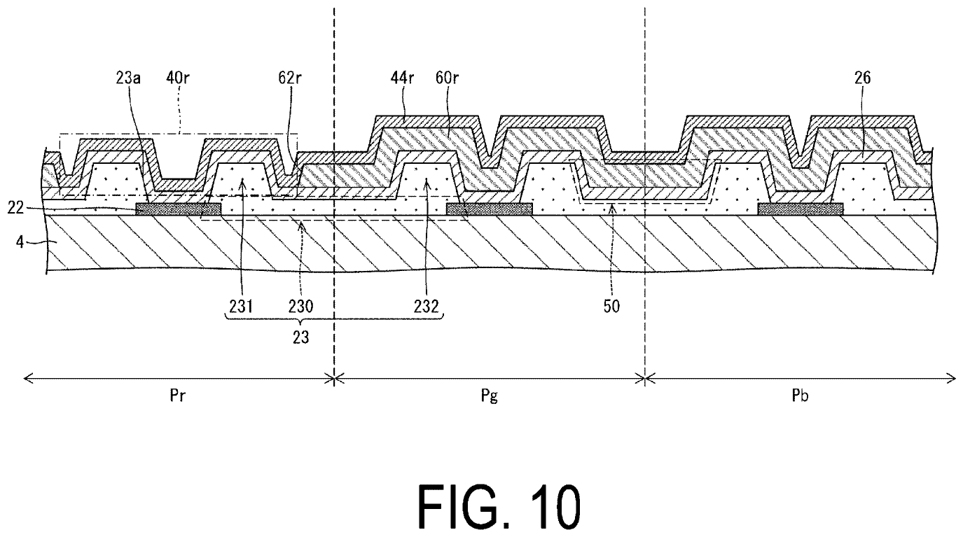

As illustrated in FIG. 10, next, a red light-emitting material layer 44r is formed above the hole injection layer 26 and on the photoresist layer 60r so that the red light-emitting material layer 44r covers the photoresist layer 60r and the bank 23 (step S46). The red light-emitting material layer 44r contains a light-emitting material that emits red light by recombining electrons and holes.

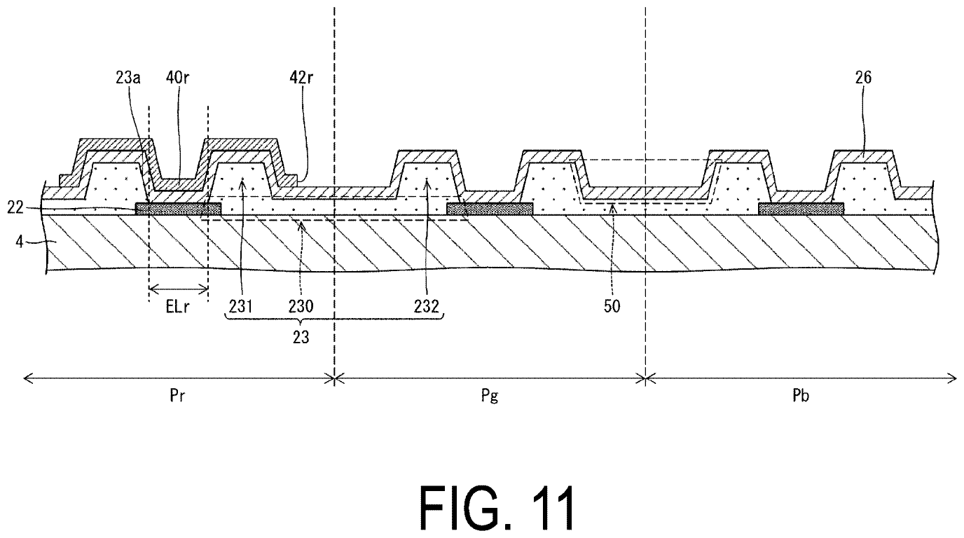

As illustrated in FIG. 11, next, the photoresist layer 60r is removed using a lift-off liquid (step S48). The lift-off liquid is a liquid that dissolves the photoresist layer 60r, and may be the same as the developing solution. In step S48, the lift-off liquid is applied or sprayed on the red light-emitting material layer 44r. The lift-off liquid passes through the red light-emitting material layer 44r, reaches the photoresist layer 60r, and dissolves the photoresist layer 60r. Next, when the lift-off liquid is removed, the photoresist layer 60r dissolved in the lift-off liquid is removed. Therefore, a portion formed on the photoresist layer 60r, out of the red light-emitting material layer 44r, is peeled off and removed. As a result, a portion formed directly on the hole injection layer 26, out of the red light-emitting material layer 44r, remains to serve as the red light-emitting layer 40r. Therefore, the red light-emitting layer 40r corresponds to the removed portion 64r of the photoresist layer 60r. In addition, washing with a washing liquid may optionally be performed.

When the lift-off liquid is removed, a flow of the lift-off liquid applies an external force to the red light-emitting layer 40r. In the end portion 42r of the red light-emitting layer 40r, a force applied to an end face of the end portion 42r and the flow of the lift-off liquid attempting to enter between the end portion 42r and the hole injection layer 26 easily act to peel off the red light-emitting layer 40r. Therefore, in order to reduce the peeling of the red light-emitting layer 40r, it is advantageous to protect at least a part of the end portion 42r from the flow of the lift-off liquid. In order to reduce peeling of the red light-emitting layer 40r, it is advantageous to protect at least a part of the end portion 42r from the liquid flow also in subsequent processes such as washing with a washing liquid, forming a green light-emitting layer 40g (step S26g), and forming a blue light-emitting layer 40b (step S26b).

The first protruding portion 231 and the second protruding portion 232 of the bank 23 according to the disclosure alleviate the liquid flow. That is, the liquid flow in the recessed portion 50 and the opening 23a of the bank 23 is weaker than an external liquid flow. Therefore, at least a part of the end portion 42r is preferably located in the recessed portion 50 or the opening 23a to be protected by the first protruding portion 231 and the second protruding portion 232. In other words, it is preferable that at least a part of the end portion 42r not be located above the upper face of the first protruding portion 231 and not be located above the upper face of the second protruding portion 232.

In order to reduce electric field concentration and short circuiting, the red light-emitting layer 40r is larger than the corresponding opening 23a of the bank 23. Therefore, it is preferable that at least a part of the end portion 42r of the red light-emitting layer 40r be located either adjacently to a side face and above the upper face of the base portion 230, adjacently to a side face of the first protruding portion 231, or adjacently to a side face of the second protruding portion 232. Further, from the viewpoint of manufacturing accuracy, in consideration of a feature that widths of the side face of the base portion 230, the first protruding portion 231, and the second protruding portion 232 are small in a plan view seen from above, it is more preferable that at least a part of the end portion 42r of the red light-emitting layer 40r be designed to be located above the upper face of the base portion 230. At least a part of the end portion 42r of the red light-emitting layer 40r is preferably located between the first protruding portion 231 and the second protruding portion 232.

This is because if at least a part of the end portion 42r is designed to be located adjacently to the side face of the base portion 230, compared to a case where such a part of the end portion 42r is not located adjacently to the side face of the base portion 230, such a part of the end portion 42r is more likely to be located at the pixel electrode 22 due to manufacturing errors. Furthermore, if the end portion 42r is designed to be located adjacently to the side face of the first protruding portion 231 or the second protruding portion 232, compared to a case where the end portion 42r is not located adjacently to the side face of the first protruding portion 231 or the second protruding portion 232, such a part is more likely to be located above the upper face of the first protruding portion 231 or the second protruding portion 232 due to manufacturing errors.

Further, in order to reduce peeling of the red light-emitting layer 40r, it is preferable to increase a joining strength between the red light-emitting layer 40r and the hole injection layer 26. In order to increase the joining strength between the red light-emitting layer 40r and the hole injection layer 26, it is preferable that an area where the red light-emitting layer 40r is in contact with the hole injection layer 26 be large. In order to increase the contact area, it is more preferable that at least a part of the red light-emitting layer 40r be formed extending over the first protruding portion 231 from an electroluminescent region ELr. The electroluminescent region ELr of the red light-emitting layer 40r is a portion formed in the opening 23a of the bank 23 in the red light-emitting layer 40r.

The photoresist layer 60r is patterned in step S42 and step S44 to be suitable for the patterning of the red light-emitting layer 40r as described above. That is, in step S42 and step S44, the photoresist layer 60r is preferably patterned such that the end portion 62r of the photoresist layer 60r is located above the bank 23, and at least a part of the end portion 62r of the photoresist layer 60r is located either adjacently to the side face and above the upper face of the base portion 230, adjacently to the side face of the first protruding portion 231, or adjacently to the side face of the second protruding portion 232.

### Formation of Green Light-Emitting Layer

The formation of the green light-emitting layer 40g (step S26g) will be described below.

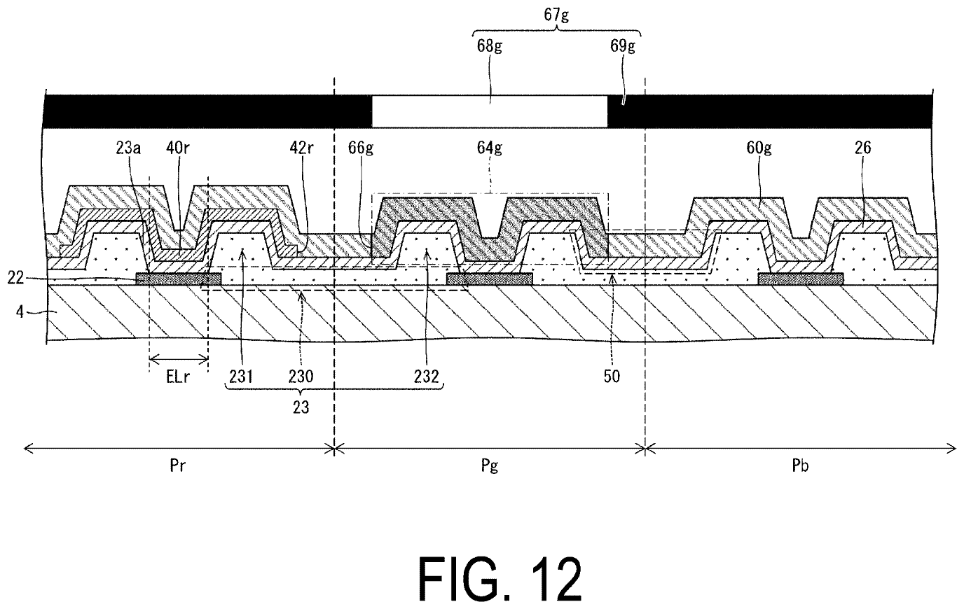

As illustrated in FIGS. 7 and 12, in step S26g, first, a photoresist layer 60g is formed on the hole injection layer 26 and the red light-emitting layer 40r so that the photoresist layer 60g covers the pixel electrode 22 and the bank 23 (step S40). The photoresist layer 60g includes a photoresist. Examples of the photoresist include acrylic-based, novolac-based, rubber-based, styrene-based, and epoxy-based photoresists. The photoresist may include the positive resist or the negative resist.

Next, the photoresist layer 60g is exposed to ultraviolet rays, electron beams, laser beams, and the like by using a photomask 67g (step S42). The photomask 67g includes a light-transmitting portion 68g with a high light transmittance and a light blocking portion 69g with a low light transmittance. As a result of such exposure, when the photoresist layer 60g includes the positive resist (see FIG. 12), a portion corresponding to the light-transmitting portion 68g of the photoresist layer 60g is soluble in a developing solution. A portion corresponding to the light blocking portion 69g of the photoresist layer 60g remains insoluble in the developing solution. Here, a portion corresponding to the light blocking portion 69g of the photoresist layer 60g is referred to as a removed portion 64g.

When the photoresist layer 60g includes the negative resist (not illustrated), a portion corresponding to the light blocking portion 69g of the photoresist layer 60g remains insoluble in the developing solution. A portion corresponding to the light-transmitting portion 68g of the photoresist layer 60g is soluble in the developing solution. Therefore, a portion corresponding to the light-transmitting portion 68g of the photoresist layer 60g is referred to as the removed portion 64g.

Next, a developing solution is used to develop the photoresist layer 60g (step S44). The developing solution may be an aqueous solution containing an inorganic alkali such as KOH or NaOH, an aqueous solution containing an organic alkali such as TMAH, or an organic solvent such as PGMEA, acetone, NMP, DMSO, and IPA. As a result of the development, the removed portion 64g is removed.

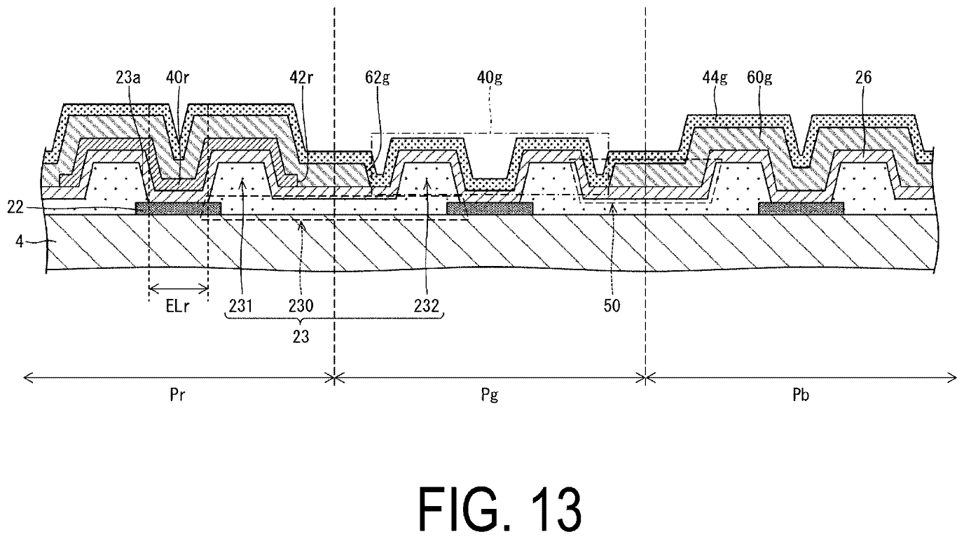

As illustrated in FIG. 13, next, a green light-emitting material layer 44g is formed above the hole injection layer 26 and on the photoresist layer 60g so that the green light-emitting material layer 44g covers the photoresist layer 60g and the bank 23 (step S46). The green light-emitting material layer 44g contains a light-emitting material that emits green light by recombining electrons and holes.

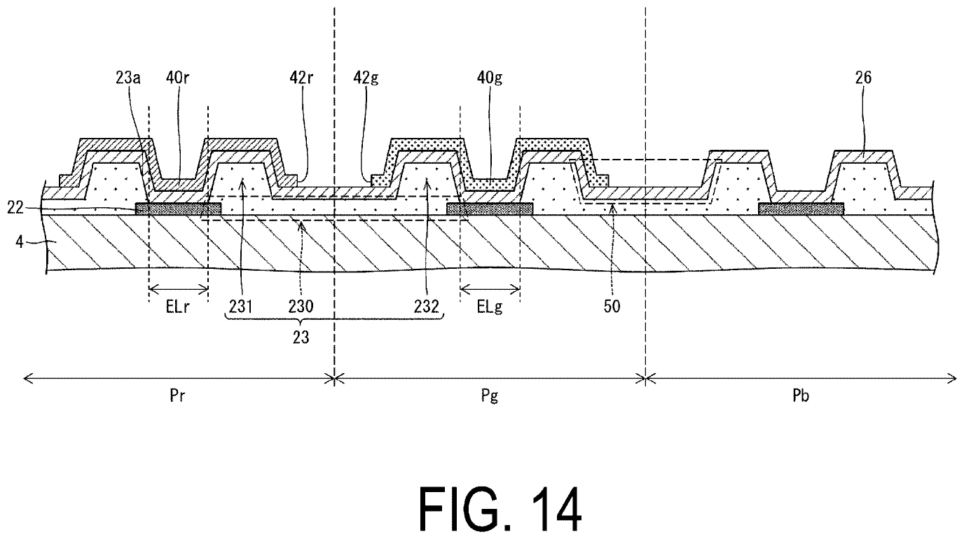

As illustrated in FIG. 14, next, the photoresist layer 60g is removed using a lift-off liquid (step S48). The lift-off liquid is a liquid that dissolves the photoresist layer 60g, and may be the same as the developing solution. In step S48, the lift-off liquid is applied or sprayed on the green light-emitting material layer 44g. The lift-off liquid passes through the green light-emitting material layer 44g, reaches the photoresist layer 60g, and dissolves the photoresist layer 60g. Next, when the lift-off liquid is removed, the photoresist layer 60g dissolved in the lift-off liquid is removed. Therefore, a portion formed on the photoresist layer 60g, out of the green light-emitting material layer 44g, is peeled off and removed. As a result, a portion formed directly on the hole injection layer 26, out of the green light-emitting material layer 44g, remains to serve as the green light-emitting layer 40g. Therefore, the green light-emitting layer 40g corresponds to the removed portion 64g of the photoresist layer 60g. In addition, washing with a washing liquid may optionally be performed.

Due to the same reason as described above for the red light-emitting layer 40r, in order to reduce peeling of the green light-emitting layer 40g, it is preferable that at least a part of the end portion 42g of the green light-emitting layer 40g be located either adjacently to a side face and above the upper face of the base portion 230, adjacently to a side face of the first protruding portion 231, or adjacently to a side face of the second protruding portion 232. It is more preferable that at least a part of the end portion 42g of the green light-emitting layer 40g be designed to be located above the upper face of the base portion 230. At least a part of the end portion 42g of the green light-emitting layer 40g is preferably located between the first protruding portion 231 and the second protruding portion 232. Further, it is more preferable that at least a part of the green light-emitting layer 40g be formed extending over the second protruding portion 232 from an electroluminescent region ELg. The electroluminescent region ELg of the green light-emitting layer 40g is a portion formed in the opening 23a of the bank 23 in the green light-emitting layer 40g.

In step S42 and step S44, the photoresist layer 60g is preferably patterned such that the end portion 62g of the photoresist layer 60g is located above the bank 23, and at least a part of the end portion 62g of the photoresist layer 60g is located either adjacently to the side face and above the upper face of the base portion 230, adjacently to the side face of the first protruding portion 231, or adjacently to the side face of the second protruding portion 232.

### Formation of Blue Light-Emitting Layer

Subsequently, formation of the blue light-emitting layer 40b (step S26b) is executed similarly to the formation of the red light-emitting layer 40r (step S26r) and the formation of the green light-emitting layer 40g (step S26g).

Due to the same reason as described above for the red light-emitting layer 40r, in order to reduce peeling of the blue light-emitting layer 40b, it is preferable that at least a part of the end portion 42b of the blue light-emitting layer 40b be located either adjacently to a side face and above the upper face of the base portion 230, adjacently to a side face of the first protruding portion 231, or adjacently to a side face of the second protruding portion 232. It is more preferable that at least a part of the end portion 42b of the blue light-emitting layer 40b be designed to be located above the upper face of the base portion 230. At least a part of the end portion 42b of the blue light-emitting layer 40b is preferably located between the first protruding portion 231 and the second protruding portion 232. Further, it is more preferable that at least a part of the blue light-emitting layer 40b be formed extending over the first protruding portion 231 or the second protruding portion 232 from an electroluminescent region ELb. The electroluminescent region ELb of the blue light-emitting layer 40b is a portion formed in the opening 23a of the bank 23 in the blue light-emitting layer 40b, for example, as illustrated in FIG. 3.

Next, the common electrode 25 is formed (step S28), and the formation of the light-emitting element layer 5 is completed.

### End Portion of Light-Emitting Layer

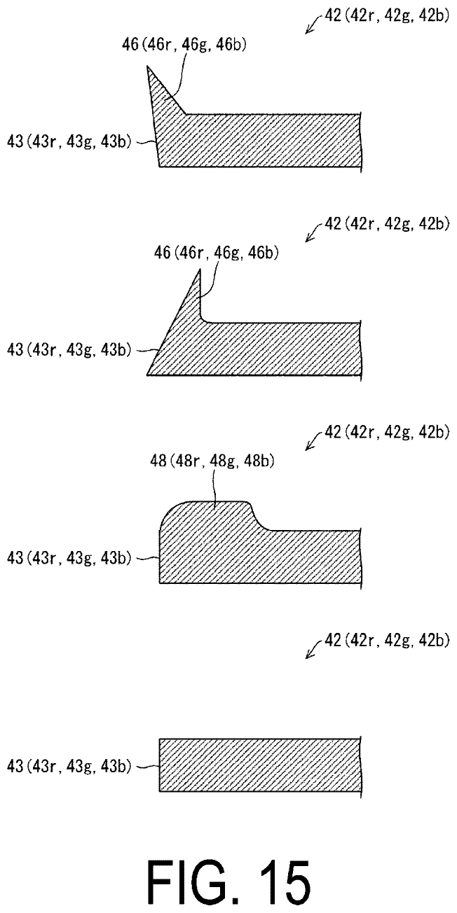

FIG. 15 is a schematic cross-sectional view illustrating a configuration of the end portion 42 of the light-emitting layer 40 illustrated in FIG. 3.

As illustrated in FIG. 15, the end portion 42 of the light-emitting layer 40 includes a burr portion 46, the end portion 42 of the light-emitting layer 40 includes a thick portion 48, or a thickness of the end portion 42 of the light-emitting layer 40 is constant.

In step S46, the red light-emitting material layer 44r creeps up the side face of the photoresist layer 60r and covers the hole injection layer 26 and the photoresist layer 60r. Such a creep-up portion easily remains as a burr on the end portion 42r of the red light-emitting layer 40r. In the disclosure, the expression “the end portion 42r of the red light-emitting layer 40r (function layer) includes a burr portion 46r” means that a portion that creeps up the side face of the first photoresist layer 60r of the red light-emitting material layer 44r (function material layer) remains as a burr at the end portion 42r of the red light-emitting layer 40r. Such creep-up may occur in any case where the side face of the first photoresist layer 60r is tapered, inversely tapered, or vertical.

Alternatively, in step S46, the red light-emitting material layer 44r may thickly remain between the side face of the photoresist layer 60r and the upper face of the hole injection layer 26, and the thickly remaining portion is likely to be left at the end portion 42r of the red light-emitting layer 40r. In the disclosure, the expression “the end portion 42r of the red light-emitting layer 40r (function layer) includes a thick portion 48r” means that the end portion 42r of the red light-emitting layer 40r does not include a burr, but a thickness of the end portion 42r of the red light-emitting layer 40r is larger than a thickness of the electroluminescent region ELr of the red light-emitting layer 40r.

In the disclosure, the expression “the end portion 42r of the red light-emitting layer 40r (function layer) is thick” means either “the end portion 42r of the red light-emitting layer 40r (function layer) includes the burr portion 46r” or “the end portion 42r of the red light-emitting layer 40r (function layer) includes the thick portion 48r”, or both. On the other hand, the expression “a thickness of the end portion 42r of the red light-emitting layer 40r (function layer) is constant” excludes the expression that “the end portion 42r of the red light-emitting layer 40r (function layer) is thick”, that is, means that the end portion 42r of the red light-emitting layer 40r includes neither the burr portion nor the thick portion, and the end portion 42r of the red light-emitting layer 40r is substantially equal in thickness to the electroluminescent region ELr (central portion) of the red light-emitting layer 40r.

Cases where the end portion 42g of the green light-emitting layer 40g includes and does not include the burr portion 46g or the thick portion 48g are expressed in a similar manner. Cases where the end portion 42b of the blue light-emitting layer 40b includes and does not include the burr portion 46b or the thick portion 48b are expressed in a similar manner.

In either case, the end portion 42 of the light-emitting layer 40 includes an end face 43.

### COMPARATIVE EXAMPLE

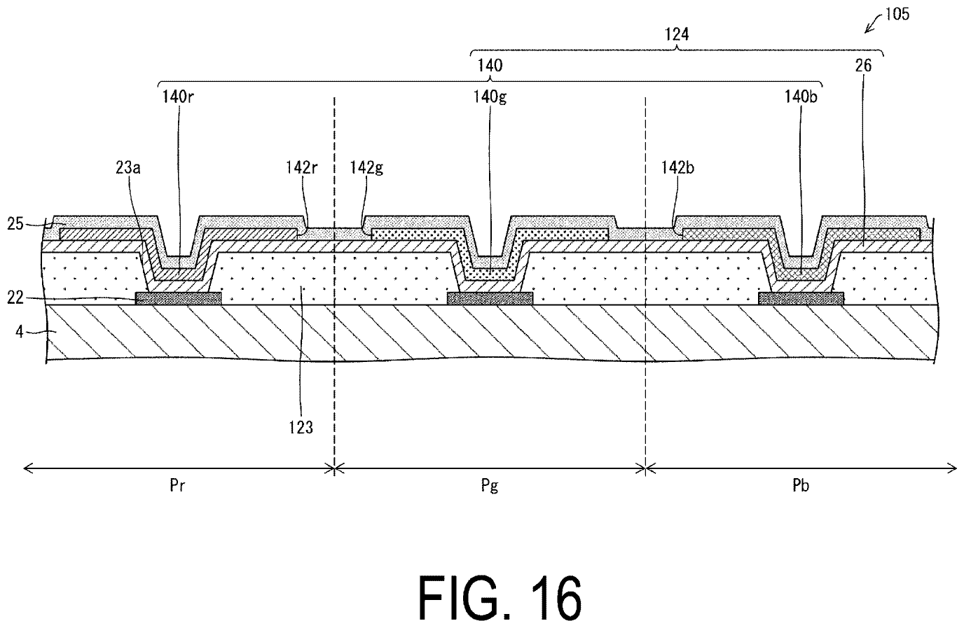

FIG. 16 is a schematic cross-sectional view illustrating a configuration of a light-emitting element layer 105 according to a comparative example.

The light-emitting element layer 105 according to the comparative example is different from the light-emitting element layer 5 according to the disclosure illustrated in FIG. 3 in that the former includes a bank 123 not including a protruding portion and includes an active layer 124 including a light-emitting layer 140 including a red light-emitting layer 140r, a green light-emitting layer 140g, and a blue light-emitting layer 140b. In other respects, the light-emitting element layer 105 according to the comparative example has a configuration equivalent to that of the light-emitting element layer 5 according to the disclosure illustrated in FIG. 3, and is manufactured by an equivalent manufacturing method.

As illustrated in FIG. 16, an end portion 142r of the red light-emitting layer 140r according to the comparative example is located above the upper face of the bank 123, and the bank 123 does not include a protruding portion. Therefore, in the manufacturing process of the light-emitting element layer 105, the end portion 142r of the red light-emitting layer 140r is not protected from the liquid flow. Therefore, the red light-emitting layer 140r is easily peeled off. Furthermore, when the end portion 142r of the red light-emitting layer 140r includes the burr portion, such a burr portion is easily peeled off. Furthermore, the green light-emitting layer 140g and the blue light-emitting layer 140b according to the comparative example are also easily peeled off, and the burr portions included in the green light-emitting layer 140g and the blue light-emitting layer 140b are also easily peeled off.

In short, the light-emitting element layer 105 according to the comparative example has a problem that the light-emitting layer 140 and the burr portion included in the light-emitting layer 140 are easily peeled off. To resolve such an issue, the light-emitting element layer 5 according to the disclosure exhibits, as described above, an effect that the light-emitting layer 40 and the burr portion 46 included in the light-emitting layer 40 are less likely to be peeled off.

### Film Discontinuity

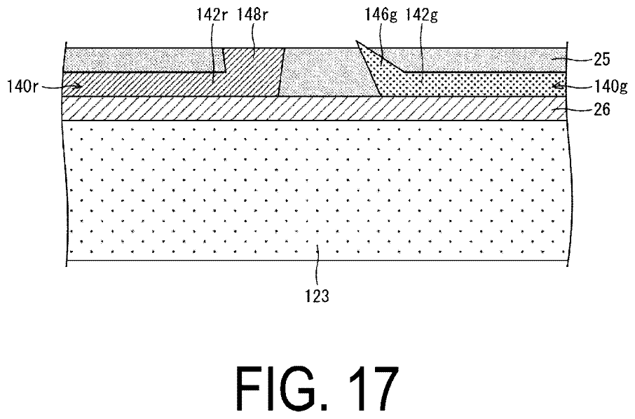

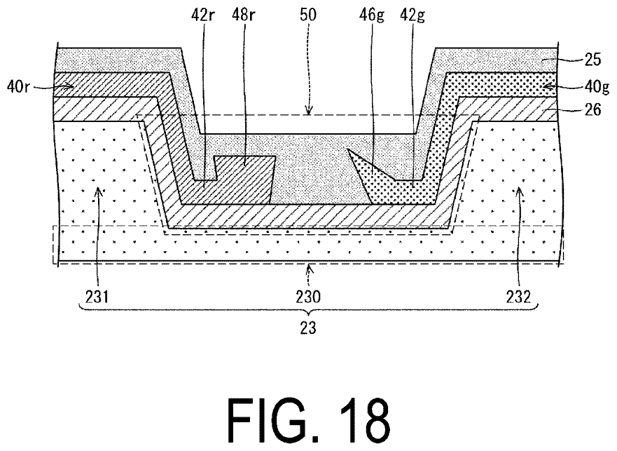

FIG. 17 is an enlarged schematic partial cross-sectional view illustrating a portion of a configuration of the light-emitting element layer 105 according to the comparative example in an enlarged manner. FIG. 18 is an enlarged schematic partial cross-sectional view illustrating a portion of a configuration of the light-emitting element layer 5 according to the disclosure illustrated in FIG. 3 in an enlarged manner.

As illustrated in FIG. 17, when the end portion 142r of the red light-emitting layer 140r according to the comparative example includes a thick portion 148r, the common electrode 25 is likely to be discontinuous. Furthermore, when the green light-emitting layer 140g and the blue light-emitting layer 140b include thick portions, the common electrode 25 is likely to be discontinuous. Similarly, when an end portion 142g of the green light-emitting layer 140g according to the comparative example includes a burr portion 146g, the common electrode 25 is likely to be discontinuous. Furthermore, when the red light-emitting layer 140r and the blue light-emitting layer 140b include burr portions, the common electrode 25 is likely to be discontinuous. The common electrode 25 is located in a layer above the red light-emitting layer 140r, the green light-emitting layer 140, and the blue light-emitting layer 140b.

In short, the light-emitting element layer 105 according to the comparative example has a problem that film discontinuity is likely to occur in an upper layer overlying the light-emitting layer 140.

On the other hand, as illustrated in FIG. 18, even in a case where the end portion 42r of the red light-emitting layer 40r according to the disclosure includes the thick portion 48r and the end portion 42g of the green light-emitting layer 40g according to the disclosure includes the burr portion 46g, the common electrode 25 is unlikely to be discontinuous. This is because portions of the common electrode 25 formed in the recessed portion 50 and the opening 23a of the bank 23 are likely to be formed thicker than the other portions.

Therefore, the light-emitting element layer 5 according to the disclosure exhibits an effect that the film discontinuity is less likely to occur in an upper layer overlying the light-emitting layer 40.

In order to exhibit such an effect, a step between the upper face of the base portion 230 and the upper faces of the first protruding portion 231 and the second protruding portion 232 is preferably larger than the thicknesses of the end portions 42r, 42g, and 42b of the red light-emitting layer 40r, the green light-emitting layer 40g, and the blue light-emitting layer 40b. More specifically, it is more preferable that such a step be larger than assumed maximum thicknesses of the burr portions 46r, 46g, and 46b and the thick portions 48r, 48g, and 48b possibly included in the end portions 42r, 42g, and 42b. The assumed maximum thickness is typically at least twice a design film thickness. To be more specific, the assumed maximum thickness of the end portion 42r of the red light-emitting layer 40r is twice or more the thickness in the electroluminescent region ELr of the red light-emitting layer 40r. Similarly, the assumed maximum thicknesses of the end portions 42g and 42b of the green light-emitting layer 40g and the blue light-emitting layer 40b are twice or more the thicknesses in the electroluminescent regions ELg and ELb of the green light-emitting layer 40g and the blue light-emitting layer 40b. Note that when the end portions 42r, 42g, and 42b overlap each other in the recessed portion 50, such a step is preferably larger than a sum of the thicknesses of the overlapping end portions 42r, 42g, and 42b. Therefore, it is preferable that the end portions 48r, 48g, and 48b not overlap each other in the recessed portion 50.

### Modified Example

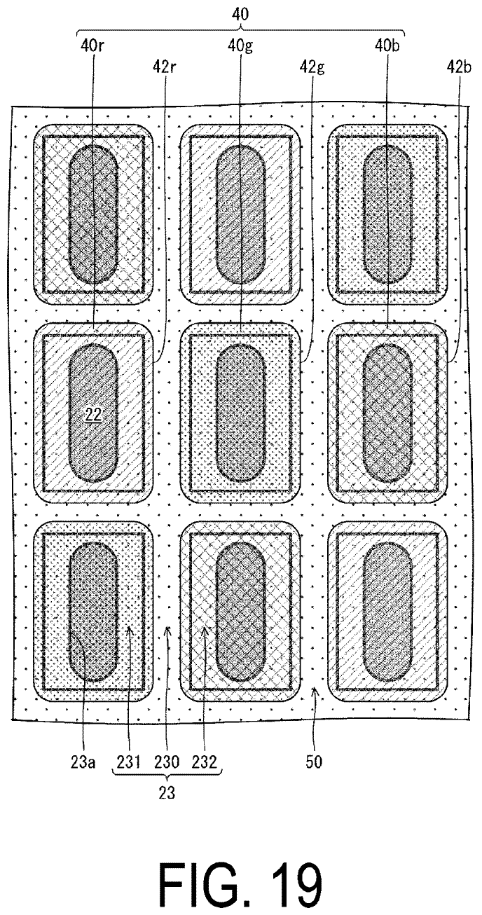

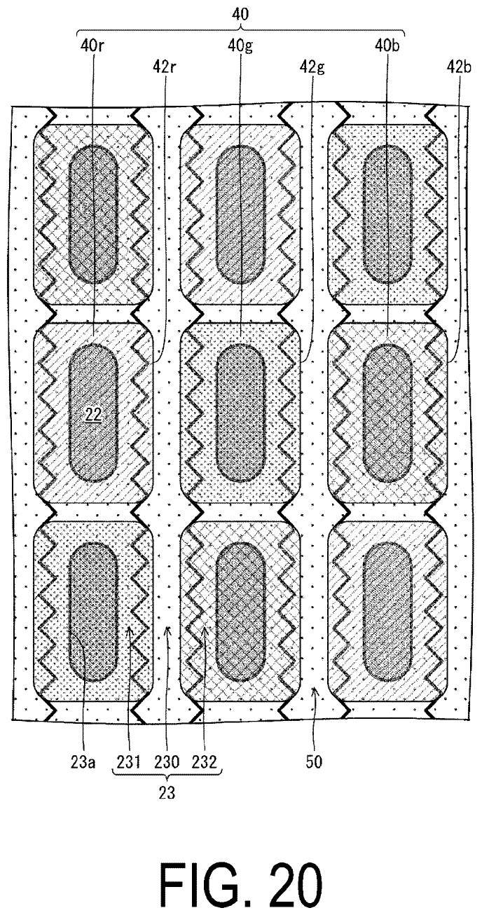

FIGS. 19 and 20 are schematic plan views each illustrating a modified example of the positional relationship between the light-emitting layer 40 and the bank 23 in the light-emitting element layer 5 illustrated in FIG. 3.

As illustrated in FIG. 19, the bank 23 is preferably formed such that the first protruding portion 231 surrounds the opening 23a (that is, the electroluminescent regions ELr, ELg, and ELb) of the bank 23 and an entire part of the end portion 42r of the red light-emitting layer 40r is located adjacently to the side face or the upper face of the base portion 230 or the side face of the first protruding portion 231 or the second protruding portion 232. This is because the entire part of the end portion 42r is protected, and thus, the peeling of the red light-emitting layer 40r is further reduced. Similarly, the bank 23 is preferably formed such that an entire part of each of the end portions 42g and 42b of the green light-emitting layer 40g and the blue light-emitting layer 40b is located adjacently to the side face or above the upper face of the base portion 230 or adjacently to the side face of the first protruding portion 231 or the second protruding portion 232. On the other hand, as illustrated in FIG. 3, when the first protruding portion 231 does not surround the opening 23a of the bank 23, an alignment accuracy of the light-emitting layer 40 with respect to the bank 23 may be low, and there is an advantage that a manufacturing efficiency of the light-emitting element layer 5 is easily improved.

As illustrated in FIG. 20, at least one side face of the first protruding portion 231 preferably includes a meandering shape or a zigzag shape. This is because a stress applied to or generated in the first protruding portion 231 is dispersed by the meandering shape or the zigzag shape. A strength of the first protruding portion 231 is improved by such stress dispersion. Similarly, at least one side face of the second protruding portion 232 also preferably includes a meandering shape or a zigzag shape.

Although not illustrated, the method and the configuration of the disclosure is applicable to a function layer other than the light-emitting layer 40, and also applicable to a function layer including a plurality of layers. The method and the configuration of the disclosure are suitable for a function layer including nanoparticles. Examples of the function layer including nanoparticles include a light-emitting layer, a charge transport layer, and a charge injection layer.

Although a configuration in which the photoresist layers 60r and 60g used as a mold (template) for patterning the light-emitting layer 40 do not remain in the light-emitting element layer 5 is described above, the scope of the disclosure is not limited thereto. For example, a configuration in which a part of the photoresist layers 60r and 60g is included in the light-emitting element layer 5 as a charge transport layer, a charge injection layer, a charge shielding layer, or the like is also included within the scope of the disclosure.

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

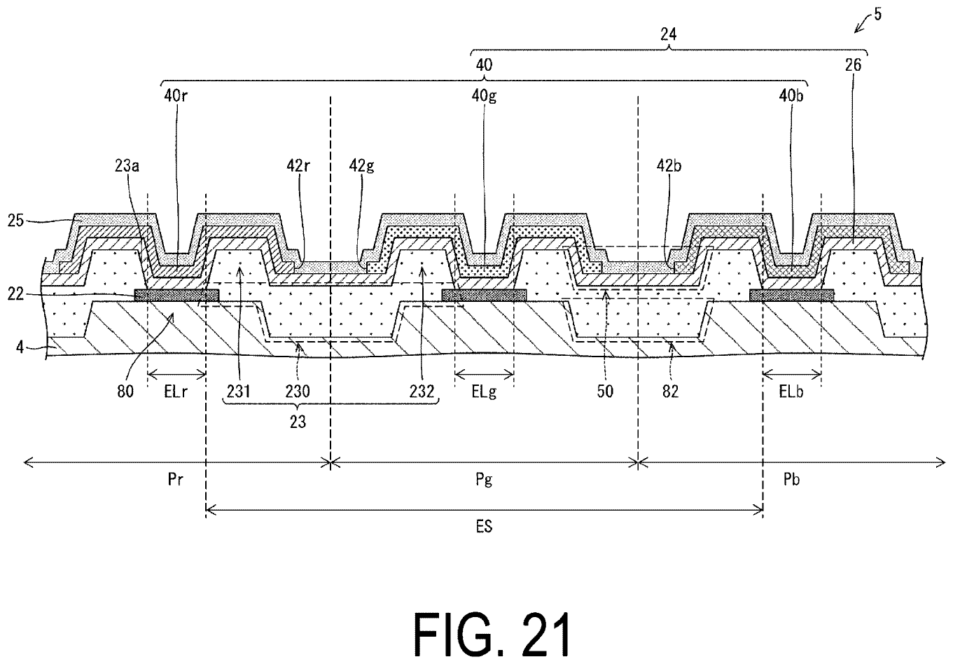

FIG. 21 is a schematic cross-sectional view illustrating an example of a configuration of the light-emitting element layer 5 according to the disclosure.

As illustrated in FIG. 21, the light-emitting element layer 5 according to a second embodiment has a configuration equivalent to that of the light-emitting element layer 5 (see FIG. 3) according to the foregoing first embodiment except that the flattening film 4 (insulating layer) includes a flat portion 80 and a depressed portion 82 depressed from the flat portion 80, and the bank 23 covers the depressed portion 82 to fill the depressed portion 82.

Therefore, a method of manufacturing the light-emitting element layer 5 according to the second embodiment is equivalent to the method of manufacturing the light-emitting element layer 5 according to the foregoing first embodiment (see FIGS. 5 to 14) except that the depressed portion 82 is formed in addition to the through hole 4a in step S14, and the photomask 71 includes the light-transmitting portion 72 and the light blocking portion 73 and does not include the semi-transparent portion in step S32.

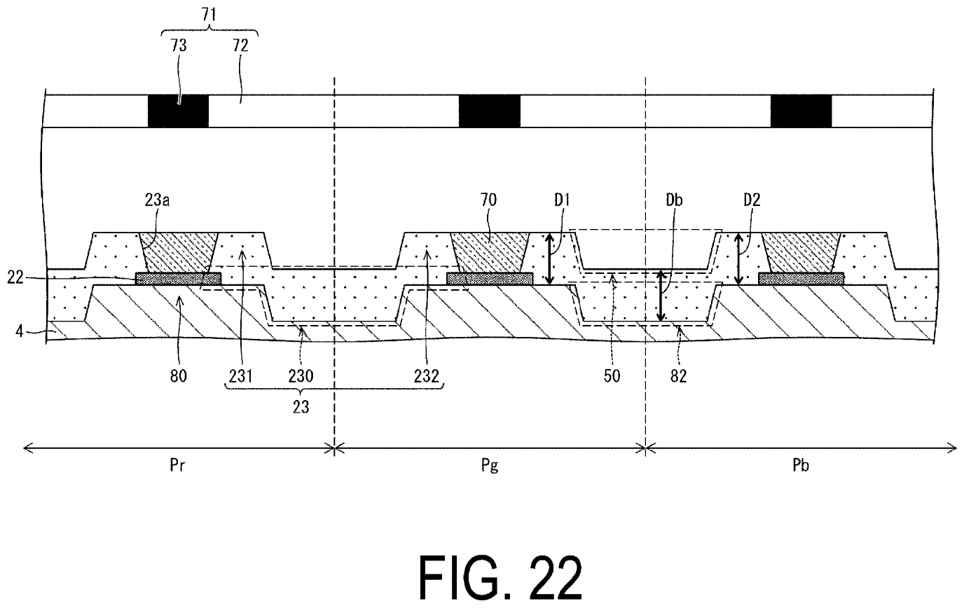

FIG. 22 is a schematic cross-sectional view illustrating an example of the method of manufacturing the light-emitting element layer 5 illustrated in FIG. 21.

As illustrated in FIG. 22, steps S10 and S12 are executed, and then, an opening including the through hole 4a and the depressed portion 82 is formed in the flattening film 4 (step S14). Next, steps S20 and S22 are executed.

In step S22, step S30 is executed. In step S30, the photoresist layer 70 is formed to follow the flattening film 4. Next, the photomask 71 not including the semi-transparent portion is used to expose the photoresist layer 70 (step S32). Next, step S34 is executed.

With the above process, when the photoresist layer 70 includes the negative resist (see FIG. 22), the base portion 230 of the bank 23 is formed from a portion corresponding to the light-transmitting portion 72 of the photoresist layer 70. From a portion corresponding to the flat portion 80 of the flattening film 4, out of a portion corresponding to the light-transmitting portion 72 of the photoresist layer 70, the first protruding portion 231 and the second protruding portion 232 of the bank 23 are formed. Therefore, from a portion corresponding to the depressed portion 82 of the flattening film 4, out of a portion corresponding to the light-transmitting portion 72 of the photoresist layer 70, the recessed portion 50 of the bank 23 is formed. In other words, the first protruding portion 231 and the second protruding portion 232 are located above the flat portion 80, and the recessed portion 50 is located above the depressed portion 82. A portion corresponding to the light blocking portion 73 of the photoresist layer 70 is removed to form the opening 23a of the bank 23.

Thereafter, steps S24, S26r, S26g, S26b and step S28 are executed.

According to the method of the second embodiment, a half-tone mask or a frame-tone mask is not used as the photomask 71, and thus, it is possible to reduce a manufacturing cost of the light-emitting element layer 5 and improve a manufacturing efficiency thereof. The method and the configuration according to the second embodiment also exhibit similar effects to that of the foregoing first embodiment.

### Modified Example

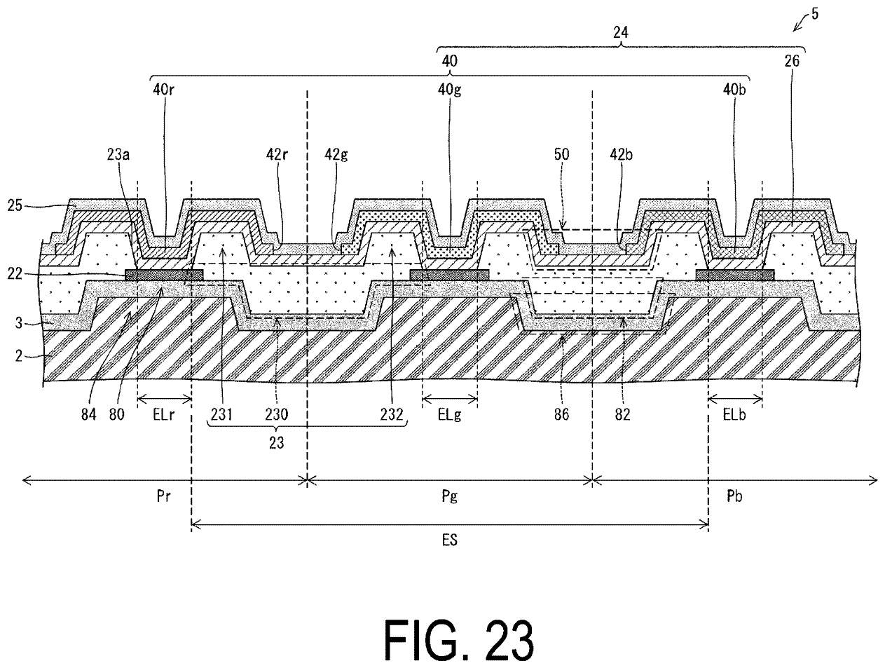

FIG. 23 is a schematic cross-sectional view illustrating a modified example of the light-emitting element layer 5 illustrated in FIG. 21.

As illustrated in FIG. 23, a depressed portion 86 depressed from a flat portion 84 may be formed in a flat glass substrate 2 (insulating layer). The thin film transistor layer 3 follows an upper face of the glass substrate 2, and thus, the thin film transistor layer 3 is provided with the depressed portion 82 depressed from the flat portion 80. An uppermost layer of the thin film transistor layer 3 is usually an insulating layer. The bank 23 covers the depressed portion 82 to fill the depressed portion 82.

In such a case, the depressed portion 86 is formed in the glass substrate 2 before the thin film transistor layer 3 is formed, and thus, the formation of the depressed portion 82 does not damage the thin film transistor layer 3. Therefore, it is possible to improve a function and a manufacturing efficiency of the light-emitting element layer 5.

### Third Embodiment

Another embodiment of the disclosure will be described below. Note that, for convenience of description, members having the same functions as those of the members described in the above-described embodiment will be denoted by the same reference numerals and signs, and the description thereof will not be repeated.

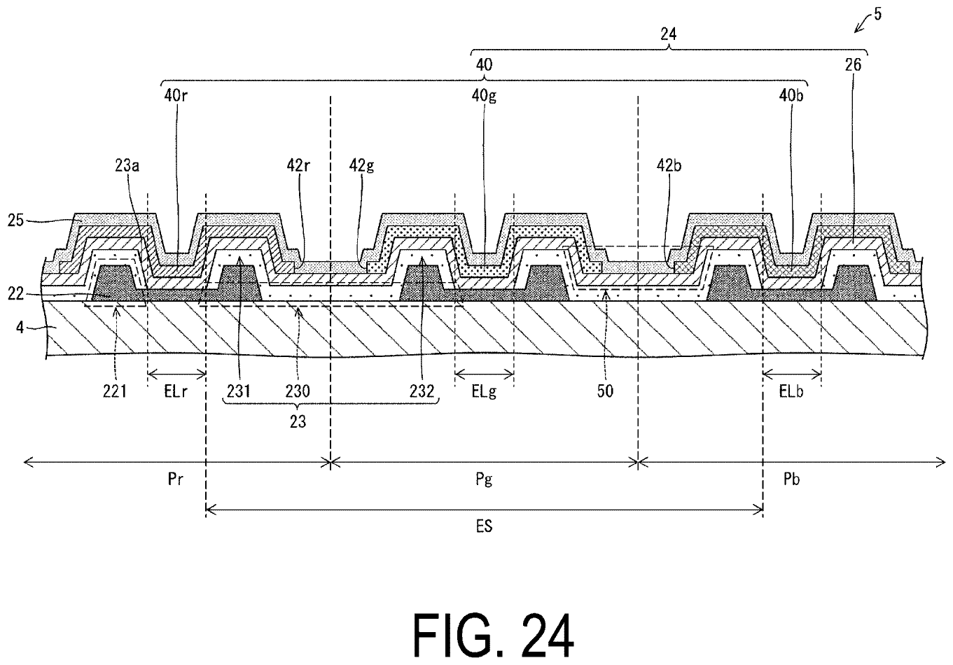

FIG. 24 is a schematic cross-sectional view illustrating an example of a configuration of the light-emitting element layer 5 according to the disclosure.

As illustrated in FIG. 24, the light-emitting element layer 5 according to a third embodiment has a configuration equivalent to that of the light-emitting element layer 5 (see FIG. 3) according to the foregoing first embodiment except that at least a part of an end portion of the pixel electrode 22 is thickened, and a distance from the upper face of the flattening film 4 to the upper face of the base portion 230 of the bank 23 is equivalent to a distance from the upper face of the pixel electrode 22 to the upper faces of the first protruding portion 231 and the second protruding portion 232 of the bank 23. Hereinafter, a thickened portion of the end portion of the pixel electrode 22 is referred to as a protruding portion 221. A thickness of the protruding portion 221 of the pixel electrode 22 is greater than a thickness of a central portion of the pixel electrode 22 corresponding to the opening 23a of the bank 23.

Therefore, a method of manufacturing the light-emitting element layer 5 according to the third embodiment is equivalent to the method of manufacturing the light-emitting element layer 5 according to the foregoing first embodiment (see FIGS. 5 to 14) except that the protruding portion 221 is formed in the pixel electrode 22 in step S20, and the photomask 71 includes the light-transmitting portion 72 and the light blocking portion 73 and does not include the semi-transparent portion in step S32.

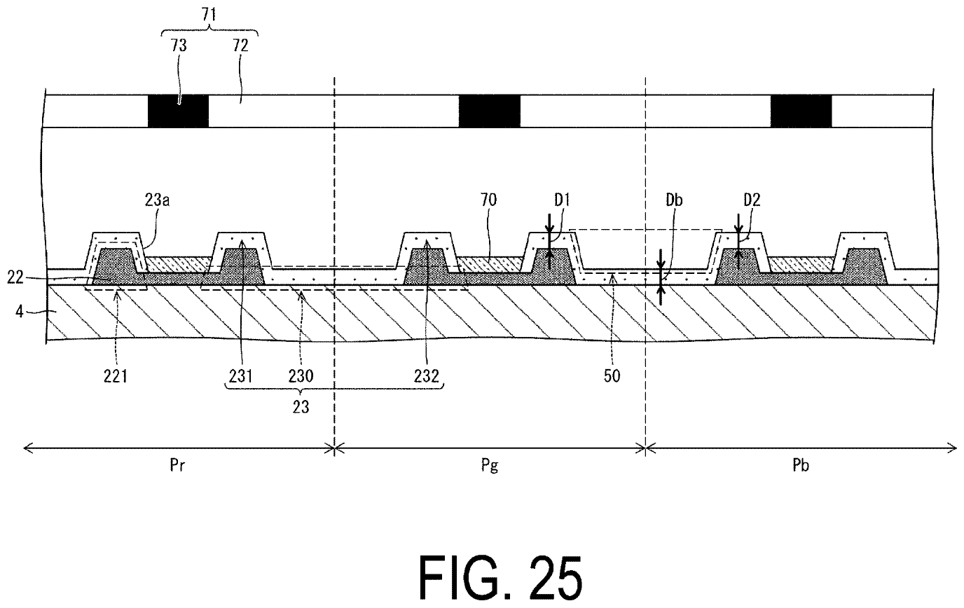

FIG. 25 is a schematic cross-sectional view illustrating an example of the method of manufacturing the light-emitting element layer 5 illustrated in FIG. 24.

As illustrated in FIG. 25, steps S10, S12, S14, S20 are executed, and then, step S22 is executed.

In step S22, step S30 is executed. In step S30, the photoresist layer 70 is formed to follow the pixel electrode 22. Next, the photomask 71 not including the semi-transparent portion is used to expose the photoresist layer 70 (step S32). Next, step S34 is executed.

By the process described above, when the photoresist layer 70 includes the negative resist (see FIG. 25), the bank 23 is formed from a portion corresponding to the light-transmitting portion 72 of the photoresist layer 70. From a portion corresponding to the protruding portion 221 of the pixel electrode 22, out of a portion corresponding to the light-transmitting portion 72 of the photoresist layer 70, the first protruding portion 231 and the second protruding portion 232 of the bank 23 are formed. Therefore, from a portion corresponding to a space between the pixel electrodes 22, out of a portion corresponding to the light-transmitting portion 72 of the photoresist layer 70, the recessed portion 50 of the bank 23 is formed. In other words, the first protruding portion 231 and the second protruding portion 232 are located above the protruding portion 221 of the pixel electrode 22, and the recessed portion 50 is not located above the pixel electrode 22. A portion corresponding to the light blocking portion 73 of the photoresist layer 70 is removed to form the opening 23a of the bank 23.

Thereafter, steps S24, S26r, S26g, S26b and step S28 are executed.

According to the method of the third embodiment, a half-tone mask or a frame-tone mask is not used as the photomask 71, and thus, it is possible to reduce a manufacturing cost of the light-emitting element layer 5 and improve a manufacturing efficiency thereof. The method and the configuration according to the third embodiment also exhibit similar effects to that of the foregoing first embodiment.

According to the configuration of the third embodiment, when the pixel electrode 22 is a reflective electrode, it is possible to reduce optical crosstalk because guided waves along the pixel electrode 22 and the bank 23 are prevented. When the pixel electrode 22 is a transmissive electrode, the efficiency of extracting light from the light-emitting element ES (so-called “external quantum efficiency”) does not decrease, as compared to a configuration in which the entire pixel electrode 22 is uniformly thick.

### Fourth Embodiment

Another embodiment of the disclosure will be described below. Note that, for convenience of description, members having the same functions as those of the members described in the above-described embodiment will be denoted by the same reference numerals and signs, and the description thereof will not be repeated.

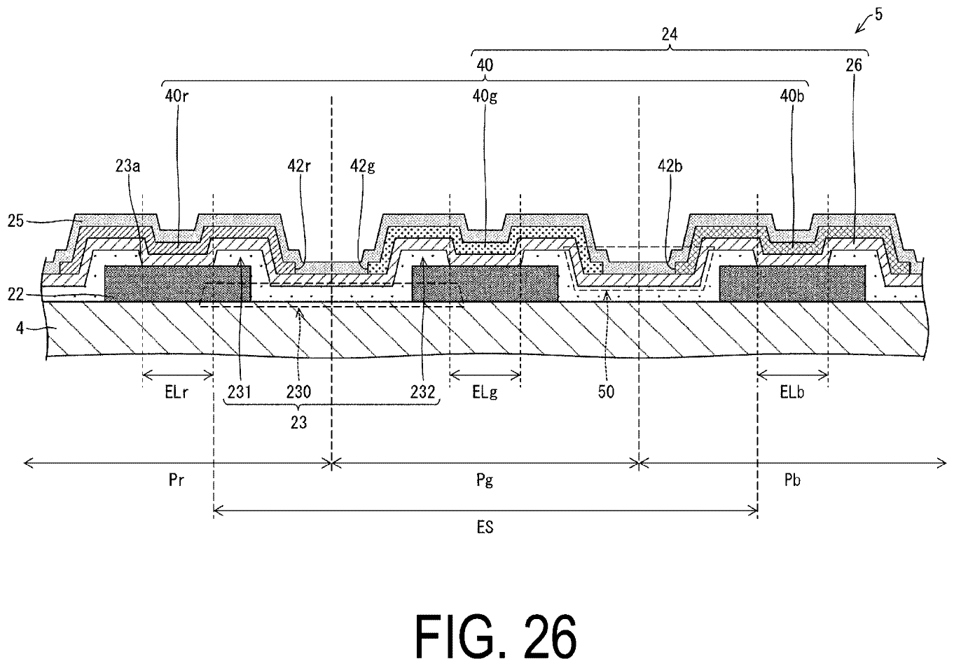

FIG. 26 is a schematic cross-sectional view illustrating an example of a configuration of the light-emitting element layer 5 according to the disclosure.

As illustrated in FIG. 26, the light-emitting element layer 5 according to a fourth embodiment has a configuration equivalent to that of the light-emitting element layer 5 (see FIG. 3) according to the foregoing first embodiment except that a whole of the pixel electrode 22 is thickened, and a distance from the upper face of the flattening film 4 to the upper face of the base portion 230 of the bank 23 is equivalent to a distance from the upper face of the pixel electrode 22 to the upper faces of the first protruding portion 231 and the second protruding portion 232 of the bank 23.

Therefore, a method of manufacturing the light-emitting element layer 5 according to the fourth embodiment is equivalent to the method of manufacturing the light-emitting element layer 5 according to the foregoing first embodiment (see FIGS. 5 to 14) except that a whole of the pixel electrode 22 is formed thickened in step S20, and the photomask 71 includes the light-transmitting portion 72 and the light blocking portion 73 and does not include the semi-transparent portion in step S32.

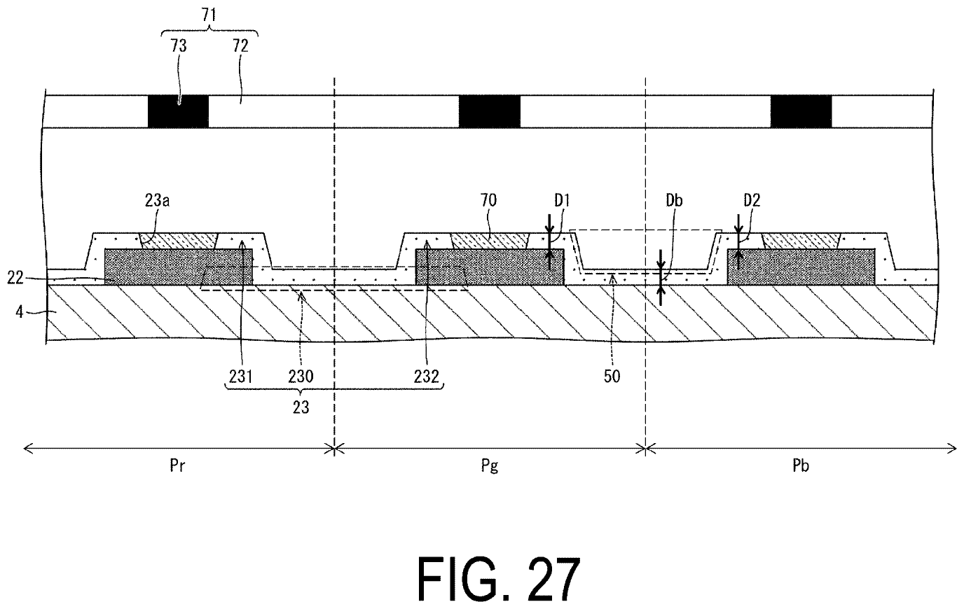

FIG. 27 is a schematic cross-sectional view illustrating an example of the method of manufacturing the light-emitting element layer 5 illustrated in FIG. 26.

As illustrated in FIG. 27, steps S10, S12, S14, S20 are executed, and then, step S22 is executed.

In step S22, step S30 is executed. In step S30, the photoresist layer 70 is formed to follow the pixel electrode 22. Next, the photomask 71 not including the semi-transparent portion is used to expose the photoresist layer 70 (step S32). Next, step S34 is executed.

By the process described above, when the photoresist layer 70 includes the negative resist (see FIG. 27), the bank 23 is formed from a portion corresponding to the light-transmitting portion 72 of the photoresist layer 70. From a portion corresponding to the pixel electrode 22, out of a portion corresponding to the light-transmitting portion 72 of the photoresist layer 70, the first protruding portion 231 and the second protruding portion 232 of the bank 23 are formed. Therefore, from a portion corresponding to a space between the pixel electrodes 22, out of a portion corresponding to the light-transmitting portion 72 of the photoresist layer 70, the recessed portion 50 of the bank 23 is formed. In other words, the first protruding portion 231 and the second protruding portion 232 are located above the pixel electrode 22, and the recessed portion 50 is not located above the pixel electrode 22. A portion corresponding to the light blocking portion 73 of the photoresist layer 70 is removed to form the opening 23a of the bank 23.

Thereafter, steps S24, S26r, S26g, S26b and step S28 are executed.

According to the method of the fourth embodiment, a half-tone mask or a frame-tone mask is not used as the photomask 71, and thus, it is possible to reduce a manufacturing cost of the light-emitting element layer 5 and improve a manufacturing efficiency thereof. The method and the configuration according to the fourth embodiment also exhibit similar effects to that of the foregoing first embodiment.

According to the configuration of the fourth embodiment, when the pixel electrode 22 is a reflective electrode, it is possible to reduce optical crosstalk because guided waves along the pixel electrode 22 and the bank 23 are prevented. The thickness of the pixel electrode 22 is uniform, and thus, there is an advantage in that the pixel electrode 22 is easily formed as compared with a configuration according to the foregoing third embodiment.

### Fifth Embodiment

Another embodiment of the disclosure will be described below. Note that, for convenience of description, members having the same functions as those of the members described in the above-described embodiment will be denoted by the same reference numerals and signs, and the description thereof will not be repeated.

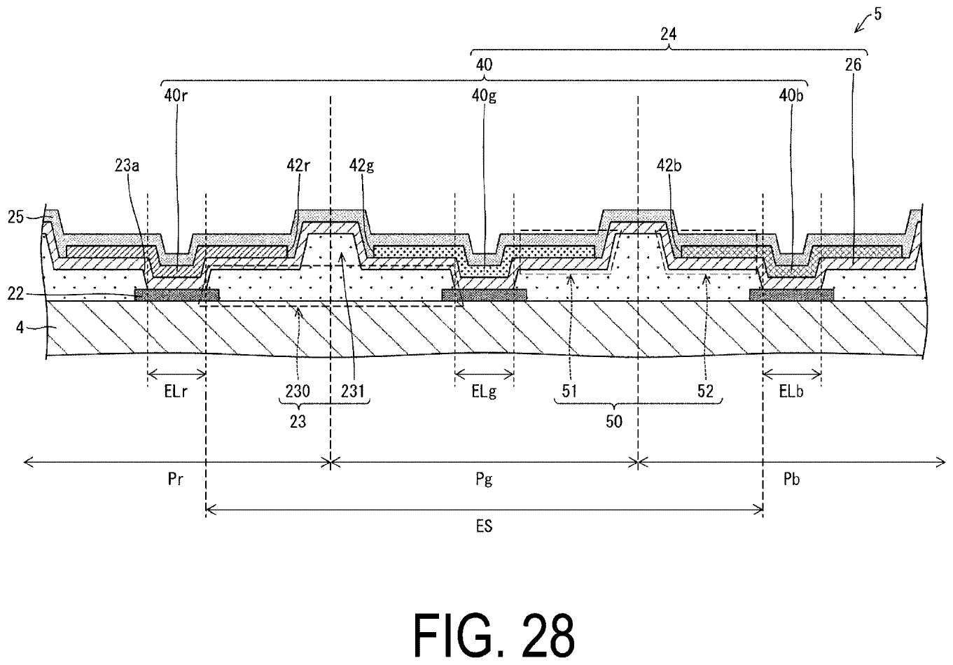

FIG. 28 is a schematic cross-sectional view illustrating an example of a configuration of the light-emitting element layer 5 according to the disclosure.

As illustrated in FIG. 28, the light-emitting element layer 5 according to a fifth embodiment has a configuration equivalent to that of the light-emitting element layer 5 (see FIG. 3) according to the foregoing first embodiment except that the bank 23 includes only the base portion 230 and the first protruding portion 231 and does not include the second protruding portion. In such a case, the recessed portion 50 includes a first recessed portion 51 between the upper face of the base portion 230 and the side face on one side of the first protruding portion 231 and a second recessed portion 52 between the upper face of the base portion 230 and the side face on the other side of the first protruding portion 231.

At least a part of the end portion 42r of the red light-emitting layer 40r is located either adjacently to the side face and above the upper face of the base portion 230 or adjacently to the side face of the first protruding portion 231. Similarly, at least a part of the end portion 42g of the green light-emitting layer 40g and at least a part of the end portion 42b of the blue light-emitting layer 40b are located either adjacently to the side face and above the upper face of the base portion 230 or adjacently to the side face of the first protruding portion 231. Therefore, the method and the configuration according to the fifth embodiment also exhibit similar effects to that of the foregoing first embodiment.

According to the configuration of the fifth embodiment, at least a part of the end portion 42r of the red light-emitting layer 40r and at least a part of the end portion 42g of the green light-emitting layer 40g are separated by the first protruding portion 231. Therefore, the end portion 42r and the end portion 42g do not overlap each other in the recessed portion 50. On the other hand, in the configuration according to the foregoing first embodiment, the end portions 42r, 42g, and 42b may overlap each other in the recessed portion 50. Therefore, according to the configuration of the fifth embodiment, it is possible to manufacture the recessed portion 50 more shallowly than that in the configuration of the foregoing first embodiment. When the recessed portion 50 is manufactured shallowly, it is possible to apply the light-emitting layer 40 into the recessed portion 50, and thus, it is possible to easily form the light-emitting layer 40 and possible to improve the manufacturing efficiency of the display device 1.

### Sixth Embodiment

Another embodiment of the disclosure will be described below. Note that, for convenience of description, members having the same functions as those of the members described in the above-described embodiment will be denoted by the same reference numerals and signs, and the description thereof will not be repeated.

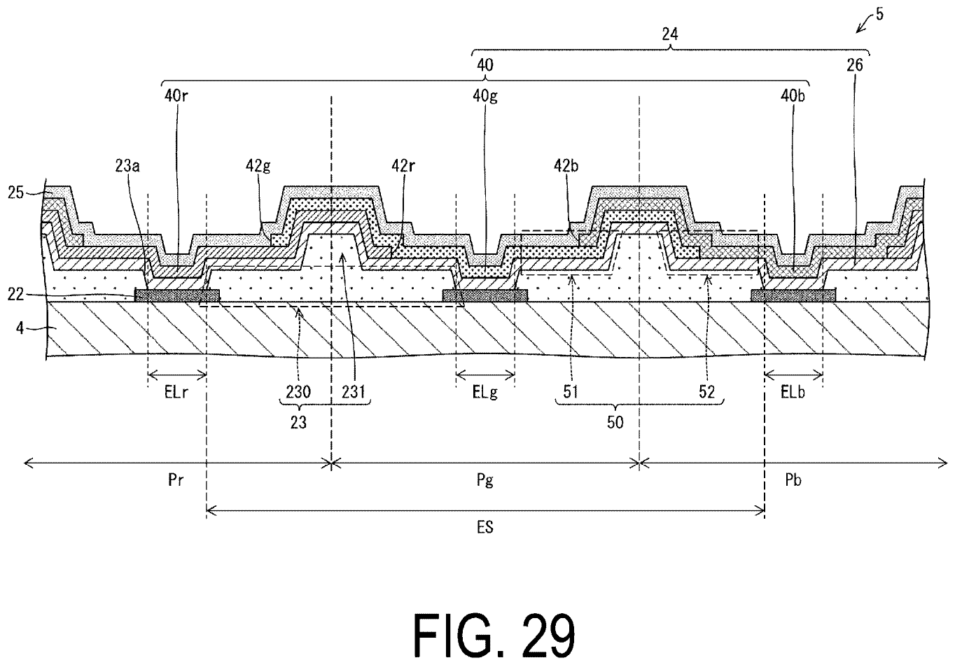

FIG. 29 is a schematic cross-sectional view illustrating an example of a configuration of the light-emitting element layer 5 according to the disclosure.

As illustrated in FIG. 29, the light-emitting element layer 5 according to a sixth embodiment has a configuration equivalent to that of the light-emitting element layer 5 (see FIG. 28) according to the foregoing fifth embodiment except that the light-emitting layers 40 of different colors overlap each other on the first protruding portion 231.

At least a part of the end portion 42r of the red light-emitting layer 40r is located either adjacently to the side face and above the upper face of the base portion 230 or adjacently to the side face of the first protruding portion 231. Similarly, at least a part of the end portion 42g of the green light-emitting layer 40g and at least a part of the end portion 42b of the blue light-emitting layer 40b are located either adjacently to the side face and above the upper face of the base portion 230 or adjacently to the side face of the first protruding portion 231. Therefore, the method and the configuration according to the sixth embodiment also exhibit similar effects to that of the foregoing fifth embodiment.

The red light-emitting layer 40r according to the sixth embodiment is formed extending over the first protruding portion 231 from the electroluminescent region ELr. Therefore, the red light-emitting layer 40r according to the sixth embodiment has a larger area where the red light-emitting layer 40r is in contact with the hole injection layer 26 than the red light-emitting layer 40r according to the foregoing fifth embodiment. Therefore, a joining strength between the red light-emitting layer 40r and the hole injection layer 26 is high, and thus, the peeling of the red light-emitting layer 40r is further reduced.

Similarly, the green light-emitting layer 40g and the blue light-emitting layer 40b according to the sixth embodiment are formed extending over the first protruding portion 231 from the electroluminescent regions ELg and ELb, and thus, the peeling of the green light-emitting layer 40g and the blue light-emitting layer 40b is further reduced.

According to the configuration of the sixth embodiment, the areas of the red light-emitting layer 40r and the green light-emitting layer 40g are larger than those in the configuration of the foregoing fifth embodiment. Therefore, the openings formed in the photoresist layers 60r and 60g are widened by the development in step S44 (see FIG. 7). Application to the inside of the opening is facilitated by widening the opening, and thus, it is possible to easily form the light-emitting layer 40, and it is possible to improve a manufacturing efficiency of the display device 1.

### Seventh Embodiment

Another embodiment of the disclosure will be described below. Note that, for convenience of description, members having the same functions as those of the members described in the above-described embodiment will be denoted by the same reference numerals and signs, and the description thereof will not be repeated.

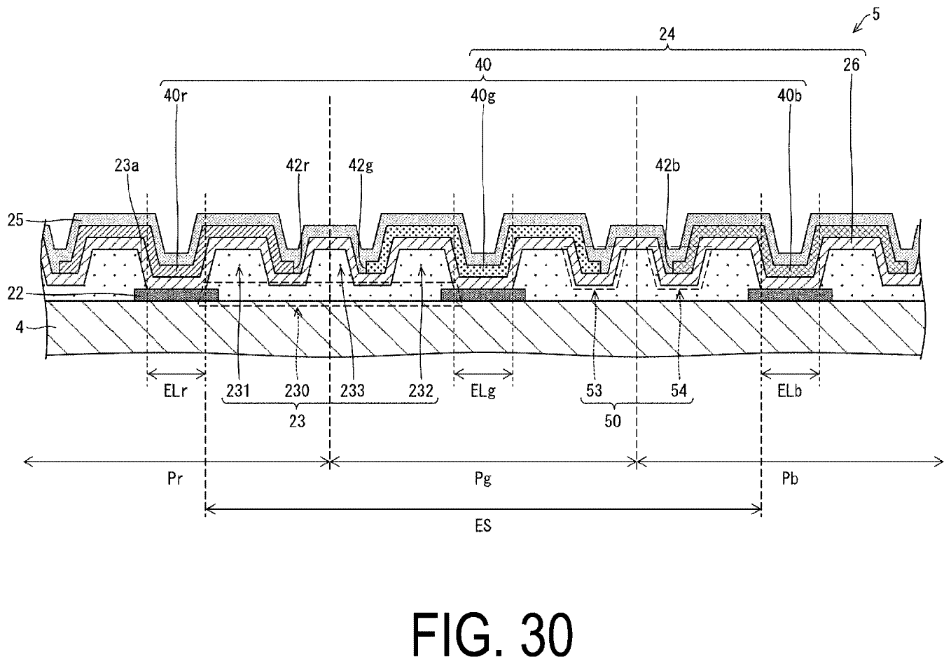

FIG. 30 is a schematic cross-sectional view illustrating an example of a configuration of the light-emitting element layer 5 according to the disclosure.

As illustrated in FIG. 30, the light-emitting element layer 5 according to the fifth embodiment has a configuration equivalent to that of the light-emitting element layer 5 (see FIG. 3) according to the foregoing first embodiment except that the bank 23 includes the base portion 230, the first protruding portion 231, and the second protruding portion 232, and further includes a third protruding portion 233.

At least a part of the red light-emitting layer 40r is formed extending over the first protruding portion 231. Further, at least a part of the end portion 42r of the red light-emitting layer 40r is located in a third recessed portion 53 between the first protruding portion 231 and the third protruding portion 233. Similarly, at least a part of the green light-emitting layer 40g is formed extending over the second protruding portion 232. Further, at least a part of the end portion 42g of the green light-emitting layer 40g is located in a fourth recessed portion 54 between the second protruding portion 232 and the third protruding portion 233.

Therefore, according to the configuration of the seventh embodiment, similarly to the configuration of the foregoing first embodiment, the red light-emitting layer 40r and the green light-emitting layer 40g are less likely to be peeled off, and an upper layer overlying the red light-emitting layer 40r and the green light-emitting layer 40g is less likely to be discontinuous.

Further, according to the configuration of the seventh embodiment, at least a part of the end portion 42r of the red light-emitting layer 40r and at least a part of the end portion 42g of the green light-emitting layer 40g are separated by the third protruding portion 233. Therefore, the end portion 42r and the end portion 42g do not overlap each other in the recessed portion 50. On the other hand, in the configuration according to the foregoing first embodiment, the end portions 42r, 42g, and 42b may overlap each other in the recessed portion 50. Therefore, according to the configuration of the seventh embodiment, it is possible to manufacture the recessed portion 50 more shallowly than that of the configuration of the foregoing first embodiment. When the recessed portion 50 is manufactured shallowly, it is possible to apply the light-emitting layer 40 into the recessed portion 50, and thus, it is possible to easily form the light-emitting layer 40 and possible to improve the manufacturing efficiency of the display device 1.

### Eighth Embodiment

Another embodiment of the disclosure will be described below. Note that, for convenience of description, members having the same functions as those of the members described in the above-described embodiment will be denoted by the same reference numerals and signs, and the description thereof will not be repeated.

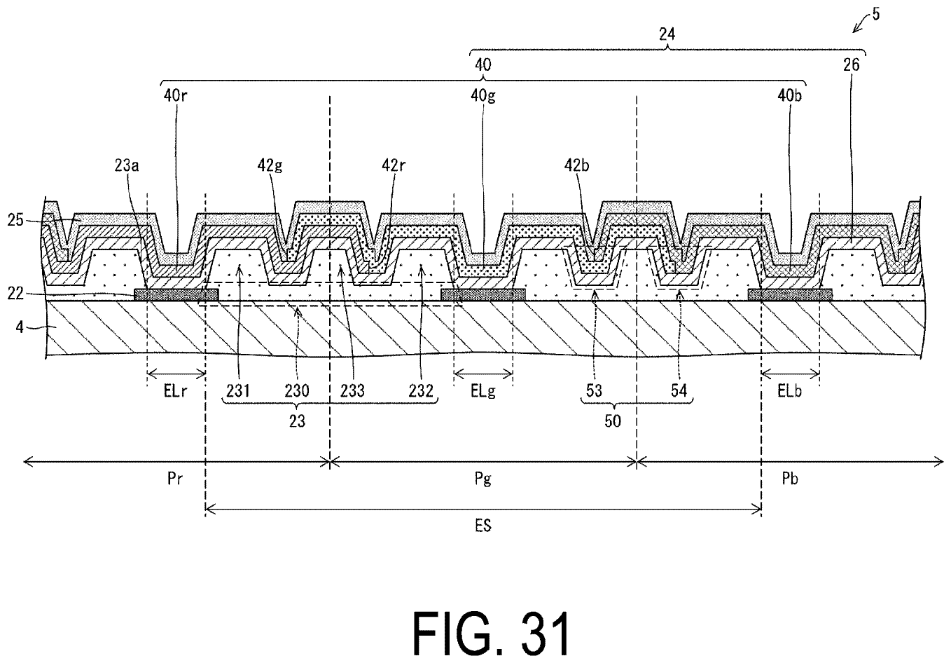

FIG. 31 is a schematic cross-sectional view illustrating an example of a configuration of the light-emitting element layer 5 according to the disclosure.

As illustrated in FIG. 31, the light-emitting element layer 5 according to an eighth embodiment has a configuration equivalent to that of the light-emitting element layer 5 (see FIG. 30) according to the foregoing seventh embodiment except that the light-emitting layers 40 of different colors overlap each other on the third protruding portion 233.

At least a part of the red light-emitting layer 40r is formed extending over the first protruding portion 231 and the third protruding portion 233. Further, at least a part of the end portion 42r of the red light-emitting layer 40r is located in the fourth recessed portion 54 between the second protruding portion 232 and the third protruding portion 233. Similarly, at least a part of the green light-emitting layer 40g is formed extending over the second protruding portion 232 and the third protruding portion 233. Further, at least a part of the end portion 42g of the green light-emitting layer 40g is located in the third recessed portion 534 between the first protruding portion 231 and the third protruding portion 233.

Therefore, according to the configuration of the eighth embodiment, similarly to the configuration of the foregoing first embodiment, the red light-emitting layer 40r and the green light-emitting layer 40g are less likely to be peeled off, and an upper layer overlying the red light-emitting layer 40r and the green light-emitting layer 40g is less likely to be discontinuous.

According to the configuration of the eighth embodiment, at least a part of the end portion 42r of the red light-emitting layer 40r and at least a part of the end portion 42g of the green light-emitting layer 40g are separated by the third protruding portion 233. Therefore, the end portion 42r and the end portion 42g do not overlap each other in the recessed portion 50. Therefore, according to the configuration of the eighth embodiment, as compared with the configuration of the foregoing first embodiment, it is possible to manufacture the recessed portion 50 more shallowly and the application into the recessed portion 50 is facilitated, and thus, it is possible to easily form the light-emitting layer 40. A joining strength is high, and thus, the peeling of the light-emitting layer 40 is further reduced.

According to the configuration of the eighth embodiment, the areas of the red light-emitting layer 40r and the green light-emitting layer 40g are larger than those in the configuration of the seventh embodiment. Therefore, the openings formed in the photoresist layers 60r and 60g are widened by the development in step S44 (see FIG. 7). Application to the inside of the opening is facilitated by widening the opening, and thus, it is possible to easily form the light-emitting layer 40, and it is possible to improve a manufacturing efficiency of the display device 1. A joining strength is high, and thus, the peeling of the light-emitting layer 40 is further reduced.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a bank including a base portion and a first protruding portion protruding from an upper face of the base portion; and
a first function layer,
wherein at least a part of an end portion of the first function layer is located above the upper face of the base portion or adjacently to a side face of the first protruding portion.

2. The light-emitting element according to claim 1,
wherein at least a part of the first function layer is formed extending over the first protruding portion.

3. The light-emitting element according to claim 1,
wherein an inclination angle of the side face of the first protruding portion is less than 90 degrees.

4. The light-emitting element according to claim 1,
wherein a step between the upper face of the base portion and an upper face of the first protruding portion is less than 10 μm.

5. The light-emitting element according to claim 1,
wherein the at least a part of the end portion of the first function layer is located above the upper face of the base portion.

6. The light-emitting element according claim 1,
wherein the first function layer has a thick end portion as compared to a portion formed in an opening of the bank.

7. The light-emitting element according to claim 1,
wherein the first function layer includes at least any one layer of a light-emitting layer, a charge transport layer, and a charge injection layer.

8. The light-emitting element according to claim 1,
wherein the bank further includes a second protruding portion protruding from the upper face of the base portion, and
the at least a part of the end portion of the first function layer is located between the first protruding portion and the second protruding portion.

9. The light-emitting element according to claim 8,
wherein a step between the upper face of the base portion and the upper face of the first protruding portion is larger than a thickness of the at least a part of the end portion of the first function layer, and
a step between the upper face of the base portion and the upper face of the second protruding portion is larger than the thickness of the at least a part of the end portion of the first function layer.

10. The light-emitting element according to claim 1,
wherein the first protruding portion surrounds an opening of the bank, and
an entire part of the end portion of the first function layer is located above the upper face of the base portion or adjacently to the side face of the first protruding portion.

11. The light-emitting element according to claim 1,
wherein the first protruding portion does not surround an opening of the bank.

12. The light-emitting element according to claim 1,
wherein at least one side face of the first protruding portion includes a meandering shape or a zigzag shape.

13. The light-emitting element according to claim 1,
wherein the first function layer includes a plurality of layers.

14. The light-emitting element according to claim 1, further comprising:
an insulating layer; and
an island-shaped electrode located on the insulating layer,
wherein the bank covers an end portion of the island-shaped electrode,
a distance from an upper face of the insulating layer to the upper face of the base portion is equivalent to a distance from a surface of the end portion of the island-shaped electrode to the upper face of the first protruding portion,
the island-shaped electrode has a uniform thickness, and
the first protruding portion is located above the end portion of the island-shaped electrode.

15. The light-emitting element according to claim 1, further comprising:
an insulating layer; and
an island-shaped electrode located on the insulating layer,
wherein the bank covers an end portion of the island-shaped electrode,
a distance from an upper face of the insulating layer to the upper face of the base portion is equivalent to a distance from an upper face of the island-shaped electrode to the upper face of the first protruding portion,
at least a part of the end portion of the island-shaped electrode is thicker than a central portion of the island-shaped electrode corresponding to an opening of the bank, and
the first protruding portion is located above the at least a part of the end portion of the island-shaped electrode.

16. The light-emitting element according to claim 1, further comprising:
an insulating layer including a flat portion and a depressed portion depressed from the flat portion,
wherein the bank covers the depressed portion, and
the first protruding portion is located above the flat portion.

17. (canceled)

18. The display device comprising the light-emitting element according to claim 147, comprising:
a second function layer including an end portion formed above the bank and located on a side opposite to the first function layer with respect to the bank,
wherein at least a part of the second function layer is located above the upper face of the base portion or adjacently to the side face of the first protruding portion.

19. The display device comprising the-light emitting element according to claim 147, comprising:
a second function layer including an end portion formed above the bank and located on a side opposite to the first function layer with respect to the bank,
wherein the bank further includes a second protruding portion protruding from the upper face of the base portion, and
at least a part of an end portion of the second function layer is located between the first protruding portion and the second protruding portion.

20. The display device according to claim 19,
wherein the bank further includes a third protruding portion protruding from the upper face of the base portion and being located between the first protruding portion and the second protruding portion,
at least a part of the first function layer is formed extending over the first protruding portion,
at least a part of the second function layer is formed extending over the second protruding portion,
the at least a part of the end portion of the first function layer is located between the first protruding portion and the third protruding portion, and
the at least a part of the end portion of the second function layer is located between the second protruding portion and the third protruding portion.

21. The display device according to claim 19,
wherein the bank further includes a third protruding portion protruding from the upper face of the base portion and being located between the first protruding portion and the second protruding portion,
at least a part of the first function layer is formed extending over the first protruding portion and the third protruding portion,
at least a part of the second function layer is formed extending over the second protruding portion and the third protruding portion,
the at least a part of the end portion of the first function layer is located between the second protruding portion and the third protruding portion, and
the at least a part of the end portion of the second function layer is located between the first protruding portion and the third protruding portion.

22. (canceled)

23. (canceled)
